(19) United States
(12) Patent Application Publication
(10) Pub. No.: US 2024/0276886 A1
(43) Pub. Date: Aug. 15, 2024

(54) A PROCESSABLE, HIGH-PERFORMANCE DIELECTRIC ELASTOMER AND MULTILAYER DIELECTRIC ELASTOMER ACTUATOR

(71) Applicant: The Regents of the University of California, Oakland, CA (US)

(72) Inventors: Qibing Pei, Los Angeles, CA (US); Erin Askounis, San Jose, CA (US); Ye Shi, Los Angeles, CA (US)

(73) Assignee: The Regents of the University of California, Oakland, CA (US)

(21) Appl. No.: 18/560,669

(22) PCT Filed: May 16, 2022
(86) PCT No.: PCT/US2022/029446

§ 371 Date: Nov. 13, 2023

Related U.S. Application Data
(60) Provisional application No. 63/188,835, filed on May 14, 2021.

(51) Int. Cl. H10N 30/857; H10N 30/20; H10N 30/50

(52) U.S. Cl. CPC H10N 30/857; H10N 30/206; H10N 30/506

(57) ABSTRACT

A dielectric elastomer including a crosslinked network comprising a polypropylene oxide) unit on a network chain or a pendant group. In another example, the dielectric elastomer is stacked in a multi-layer dielectric elastomer structure comprising two adjacent dielectric elastomer layers, a layer of a. conductive network sandwiched between the two adjacent dielectric elastomer layers, and. a polymer layer binding the conductive network and the two adjacent dielectric elastomer layers. The dielectric elastomer can be used as an actuator or artificial muscle in a variety of robotic, haptic, or wearable devices. In one or more examples, the dielectric elastomer has a strain, including an area strain, greater than least 100% in response to the electric field less than 150 Volts per micron and converts at least 10% of inputted electrical energy to mechanical work.

### CROSS REFERENCE TO RELATED APPLICATIONS

This application claims the benefit under 35 USC 119(e) of co-pending and commonly assigned U.S. Provisional Patent Application Ser. No. 63/188,835, filed May 14, 2021, by Qibing Pei, Erin Askounis, and Ye Shi, entitled “A PROCESSABLE, HIGH-PERFORMANCE DIELECTRIC ELASTOMER AND MULTILAYER DIELECTRIC ELASTOMER ACTUATOR, which application is incorporated by reference herein.

### STATEMENT REGARDING FEDERALLY SPONSORED RESEARCH AND DEVELOPMENT

This invention was made with government support under Grant Number HR0011-19-C-0043, awarded by the U.S. Department of Defense, Defense Advanced Research Projects Agency. The government has certain rights in the invention.

### BACKGROUND OF THE INVENTION

### 1. Field of the Invention

The present disclosure relates to dielectric elastomers and methods of making the same.

### 2. Description of the Related Art

Dielectric elastomer (DE) materials can act as deformable capacitors to generate mechanical work in response to an electric field. However, current widely used DEs are based on acrylic and silicone elastomers commercially manufactured for different purposes. Acrylic based DEs require pre-stretching to achieve high actuation strains and lack processing flexibility. Silicone based DEs allow for processability and rapid response, but produce much lower strains.

### SUMMARY OF THE INVENTION

A processable, high-performance dielectric elastomer (PHDE) with a bimodal network structure and hydrogen-bonding crosslinks is synthesized. The dielectric elastomer, comprises a crosslinked network comprising a propylene oxide unit on a network chain or a pendant group.

Embodiments of the dielectric elastomer exhibit surprisingly beneficial properties for use as an actuator. In one or more examples, the PHDE exhibits a maximum area strain of 190% and maintains strain higher than 100% at 2 Hz, without prestretching. The dielectric actuator can also be configured as a multilayer PHDE actuator that achieves strains greater than 100% at 2 Hz. Such multilayer actuators can be fabricated by a novel dry stacking process. Exemplary PHDEs achieved actuation strains comparable to that of the best highly prestretched acrylic elastomers, with fast response and high processability afforded by silicone elastomers, thus becoming a promising artificial muscle material for the fabrication of soft robots, haptic and wearable devices.

Illustrative, non-exclusive examples of inventive subject matter according to the present disclosure are described in the following enumerated paragraphs:

1. A dielectric elastomer, comprising.
a crosslinked network comprising a poly(propylene oxide) unit on a network chain or a pendant group, wherein the pol(propylene oxide) unit comprises the structure —O—(C₃H₆O)ₙ— and n is and integer greater than or equal to 1 (e.g., 2≤n≤10 or n is in a range of 2-10)

2. The dielectric elastomer of example 1, wherein the crosslinked network is formed by polymerization of a formulation comprising a difunctional monomer comprising a poly(propylene oxide) unit or a monofunctional monomer comprising a poly(propylene oxide) unit, wherein the poly(propylene oxide) unit constitutes 50 wt % or more in the formulation.

3. The dielectric elastomer of example 1 wherein the crosslinked network is formed by polymerization of a formulation comprising a difunctional monomer comprising a poly(propylene oxide) unit having a molecular weight at least 2000 g/mol and a difunctional monomer having a molecular weight less than 2000 g/mol.

4. The dielectric elastomer of example 2, wherein the formulation comprises at least one photoinitiator.

5. The dielectric elastomer of example 1, wherein the crosslinked network is formed by polymerization of a formulation comprising an oligomer comprising a urethane unit, a difunctional monomer comprising a poly(propylene oxide) unit, a monofunctional reactive diluent, and a photoinitiator.

6. The dielectric elastomer of example 5, wherein the monofunctional reactive diluent is selected from monomers comprising a poly(propylene oxide) unit, a butyl group, an isobornyl group, a carboxylic acid group, a 2-ethylhexyl group, or mixtures thereof.

7. The dielectric elastomer of example 5, wherein the oligomer comprising the urethane unit is a difunctional monomer having a molecular weight greater than 2000 g/mol.

8. The dielectric elastomer of any of the examples 2 through 7, wherein the formulation comprises at least one polymerizable functional group selected from the group containing acrylate, a methacrylate, or mixtures thereof.

9. The dielectric elastomer of any of the examples 2 through 8, wherein the difunctional monomer comprising the poly(propylene oxide) unit has a molecular weight less than 2000 g/mol.

10. The dielectric elastomer of example 9, wherein the difunctional monomer comprising the poly(propylene oxide) unit comprises an oligo(propylene oxide) and two terminal polymerizable groups.

11. The dielectric elastomer of example 2, wherein the monofunctional monomer comprising the poly(propylene oxide) unit comprises an oligo(propylene oxide) with a molecular weight less than 500 g/mol.

12. An actuator comprising the dielectric elastomer of any of the examples 1-11, further comprising electrodes on the dielectric elastomer, wherein an electric field applied between two positions on the dielectric elastomer or across a thickness of the dielectric elastomer, in response to a voltage applied to the electrodes, actuates a deformation of stretching the dielectric elastomer that outputs mechanical work.

13. The actuator of example 12, wherein the dielectric elastomer has a strain, including an area strain, greater than at least 20% in response to the electric field less than 150 Volts per micron.

14. The actuator of example 13, wherein the dielectric elastomer maintains the strain after 50 cycles at an actuation frequency of at least 2 Hz.

15. The actuator of example 14, wherein the dielectric elastomer deforms into a dome shape upon application of the electric field using electrodes distributed across the dielectric elastomer.

16. The actuator of example of any of the examples 12-15, comprising a stack of a plurality of the dielectric elastomers.

17. A process for forming a dielectric elastomer film, comprising:
(1) preparation of a liquid formulation comprising a network forming oligomer and at least a difunctional monomer comprising a poly(propylene oxide) unit or a monofunctional monomer comprising a poly(propylene oxide) unit, wherein the pol(propylene oxide) unit comprises the structure —O—(C₃H₆O)ₙ— and n is and integer greater than or equal to 1; and
(2) casting the liquid formulation into a layer on a substrate; and
(3) curing the liquid formulation by exposure to at least one of ultraviolet light, visible light, or heat.

18. The process of forming the dielectric elastomer film as in example 17, wherein the substrate is pre-coated with a release agent.

19. The process of forming the dielectric elastomer film as in example 18, wherein the release agent comprises polyacrylic acid, polystyrene sulfonic acid, polystyrene sulfonate, or mixtures thereof.

20. A multi-layer dielectric elastomer structure comprising two adjacent dielectric elastomer layers, a layer of a conductive network sandwiched between the two adjacent dielectric elastomer layers, and a polymer layer binding the conductive network and the two adjacent dielectric elastomer layers.

21. The multi-layer dielectric elastomer structure of example 21, wherein the conductive network is formed by conductive materials selected from the group consisting of single walled carbon nanotubes, multi walled carbon nanotubes, carbon nanopowder, metal nanowires, metal nanoparticles, conductive polymer, and mixtures thereof.

22. The multi-layer dielectric elastomer structure of example 20 or 21, wherein the two adjacent dielectric elastomer layers have the same thickness.

23. The multi-layer dielectric elastomer structure of any of the examples 20-22, wherein the two adjacent dielectric elastomer layers have a thickness in the range between 5 and 100 micrometers.

24. The multi-layer dielectric elastomer structure of any of the examples 20-23, wherein the polymer binding layer is a dielectric elastomer with a thickness less than one tenth of the thickness of the adjacent dielectric elastomer layers.

25. The multi-layer dielectric elastomer structure of example 20, comprising n layers of dielectric elastomer layers comprising one or more pairs of the two adjacent dielectric elastomer layers, (n−1) layers of the conductive network, each of the layers sandwiched between a different one of the pairs of the two adjacent dielectric elastomer layers, and (n−1) of the polymer layers each binding the layer conductive network and the two adjacent dielectric elastomer layers, where n is 2 or larger.

26. A method of preparation of the multi-layer dielectric elastomer structure of example 20, comprising at least:
(1) preparing multiple dielectric elastomer films;
(2) forming the layer of the conducting network on at least one of the multiple dielectric elastomer films;
(3) depositing a layer of a liquid polymerizable formulation onto the layer of the conductive network;
(4) laminating the at least one of the dielectric elastomer films having the conductive network and layer of a liquid polymerizable formulation with another one of the multiple dielectric elastomer films;
(5) curing the layer of liquid polymerizable formulation under ultraviolet (UV) irradiation and/or heating to form the polymer layer binding the conductive network and the two adjacent dielectric elastomer layers.

27. The method of preparation of the multi-layer dielectric elastomer structure of example 26, wherein the multiple dielectric elastomer films are formed on a release substrate, and the substrate was removed after the curing step to form the polymer layer binding the conductive network and the two adjacent dielectric elastomer layers.

28. An actuator comprising the multi-layer dielectric elastomer structure of example 25, further comprising electrodes connected to the layers of the conductive network sandwiched between the two adjacent dielectric elastomer layers, wherein an electric field applied between two positions on the layers of the conductive network, in response to a voltage applied to the electrodes, actuates a deformation of stretching the multi-layer dielectric elastomer that outputs mechanical work.

29. An artificial muscle comprising the dielectric elastomer of any of the examples 1-28.

30. A robot comprising the artificial muscle of example 29, wherein the artificial muscle is used to move or propel the robot or move the robot's limbs.

31. The robot of example 30, wherein the robot uses the artificial muscle to push or jump the robot off the ground.

32. A wearable device, article of clothing, or haptic device, comprising the dielectric actuator of any of the examples.

33. The actuator of any of the examples 12-16 or 28 wherein the dielectric elastomer converts at least 10% of electrical energy inputted through the electrodes into the mechanical work.

34. The actuator of any of the examples 12-16, 28, or 33, wherein the actuator is compliant.

35. The actuator of any of the examples 12-16, 28, or 33, wherein the actuator comprises a deformable capacitor and the electric field generates an electrostatic interaction between the electrodes, known as a Maxwell stress (p), which compresses the dielectric elastomer in the thickness direction and expands it in area.

36. A dielectric elastomer, comprising:
a polyacrylate or polymethacrylate crosslinked with crosslinkers comprising at least a poly(propylene oxide) unit or moiety.

37. The elastomer of example 36, wherein the polyacrylate comprises a copolymer comprising butyl acrylate (BA) and isobornyl acrylate (IBOA) and the crosslinkers comprise urethane diacrylate (UDA) and propoxylated neopentyl glycol diacrylate (PNPDA).

38. The dielectric elastomer of any of the examples 36-37, wherein:
the polyacrylate or polymethacrylate, or a wt/o of the components of a copolymer comprising the polyacrylate or polymethacrylate are selected to achieve a desired Young's modulus, and a wt % of the poly(propylene) oxide in the elastomer is selected to tune the cross-linking density so as to tailor a stress-strain relationship and stretch ratio of the dielectric elastomer for use as an actuator outputting mechanical work in response to application of an electric field across the dielectric elastomer.

39. The dielectric elastomer of example 38, wherein the wt % are tailored so that the dielectric elastomer has an area strain, greater than at least 20% in response to an electric field less than 150 Volts per micron applied across the elastomer.

40. The dielectric elastomer of any of the examples 36-39 wherein the crosslinkers include short chains and long chains that are longer and have a larger molecular weight than the short chains and wherein the long chains comprise the poly(propylene oxide) unit or moiety.

41. The dielectric elastomer of any of the examples having the structure illustrated in FIG. 1f or FIG. 1g.

42. An actuator comprising the elastomer of any of the examples 36-41.

43. The device of any of the examples 28-35 comprising the dielectric elastomer of any of the examples 36-41.

44. A processable, high-performance dielectric elastomer (PHDE) with a bimodal network structure is synthesized, and its electromechanical properties are tailored by adjusting crosslinkers and hydrogen bonding within the elastomer network. The PHDE combines the best of acrylic elastomers and silicones. It exhibits a maximum areal strain of 190% and maintains strain higher than 110% at 2 Hz, without prestretching.

45. A novel dry stacking process with high efficiency, scalability, and yield is developed to fabricate multilayer actuators. The resulted PHDE stacks maintain the high actuation performance of single layer films, thus enabling fabrication of DE devices, such as spider actuators and multifunctional roll actuators.

46. An artificial muscle comprising the dielectric elastomer of any of the examples useful for the fabrication of soft robots, haptic and wearable devices.

### BRIEF DESCRIPTION OF THE DRAWINGS

Referring now to the drawings in which like reference numbers represent corresponding parts throughout:

FIG. 1. Synthesizing bimodal networked DEs with soft crosslinkers and hydrogen bonds for high-performance actuation. (A) Schematic illustration of the design rules for DE with bimodal network structure. (B) Molecular structures of acrylates and diacrylates used for the synthesis of bimodal networked DE. (C) Stress-strain relationships of PHDE, bimodal DE materials with different concentrations (wt/o) of PNPDA or HDDA and VHB 4905 without prestrain. The complete curves of PNPDA 0 and VHB 4905 are shown in FIG. 9. (D) Static actuation of PHDE, bimodal DE materials with different concentrations of PNPDA and VHB 4905 with 300% biaxial prestrain, measured on a diaphragm. Carbon grease was used as the compliant electrodes. (E) Cyclic actuation of PHDE and bimodal DE without AA under a 2 Hz square wave voltage of 4.5 kV for 100 cycles. (F) Example structure of the dielectric elastomer. (G) Example structure of the dielectric elastomer comprising an acrylate. (H) Illustration of formation of two-point hydrogen bonded dimer between acrylic acid units.

FIG. 2. Energy density and power density properties of PHDE. (A) Energy density of single layer PHDE films measured at specified loads. (B) Energy density at different frequencies. The driving voltage is 2.5 kV. (C) Average power density of single layer PHDE tested in pure-shear mode with different loads. (D) Performance comparison of PHDE to natural muscles and other DEAs reported in literatures. (E) Ball toss by the PHDE actuator. (F) A jumping robot fabricated with a PHDE actuator.

FIG. 3. Multilayer PHDE actuators enabled by a novel dry stacking method. (A) Diagram of “dry stacking” for multilayer PHDE actuator fabrication. (B) Photo of a 4″ by 5″ 10-layer PHDE stack with 20 actuators. (C) SEM images of cross-section view of a PHDE stack. (D) Static actuation of single layer and 10-layer PHDE films, tested on a diaphragm. CNT was used as compliant electrodes. (E) Frequency response of single layer and 10-layer PH DE actuators under 3.5 kV (square wave, 50% duty cycle).

FIG. 4. New actuators enabled by multilayer PH DE. (A) A PHDE spider actuator lifts a 200 g load at 2.5 kV. (B) Schematic illustration of fabrication of PHDE roll actuators. The inset shows the photos of a PHDE roll. (C) A PHDE roll actuator lifts 100 g load at 0.5 Hz. (D) Photograph of a PHDE roll pump. (E) Normalized flow rates (L/Lo) during various mechanical manipulations of the pump. The pump is driven at 2.5 kV at 10 Hz while bent at 90° twisted axially, and hammered. The initial flow rates and the recovery flow rates are also shown.

FIG. 5. (A) NMR spectra of CN9021. (B) GPC curve of CN9021. (C) NMR spectra of PNPDA.

FIG. 6. (A) Stress-strain relationships of bimodal DE materials with different concentrations (wt %) of HDDA and PNPDA. (B) Static actuation of bimodal DE materials with 3.5 wt % of HDDA and 10 wt % of PNPDA.

FIG. 7. (A) Molecular structures of different short-chain crosslinkers. (B) Stress-strain curves and (C) static actuation performance of DEs with different short-chain crosslinkers.

FIG. 8. Swelling ratio and gel fraction of different bimodal networked Des

FIG. 9. Stress-strain curves of PNPDA 0 and VHB 4905 without prestrain.

FIG. 10. FTIR spectra of DEs with different AA contents.

FIG. 11. (A) Mechanical loss factors (tan δ) of bimodal DE materials with different amounts of AA at room temperature. (B) Stress-strain relationships of bimodal DE materials with different amounts (parts by weight) of AA.

FIG. 12. Cyclic tensile tests of PHDE at different strains: (A) 80%, (B) 100%, and (C) 120%.

FIG. 13. (A) Loss factor (Tan δ) of PHDE and DE without AA from −50° C. to 100° C. (B) Storage modulus of PHDE and DE without AA from −50° C. to 100° C.

FIG. 14. (A) Static actuation of bimodal DEs with different amounts of AA. (B) Cyclic actuation of bimodal DEs with different amounts of AA at 2 Hz for 100 cycles.

FIG. 15. Storage modulus and tan δ of PHDE at different frequencies FIG. 16. Voltage-stretch curve Φ(λ) and breakdown-stretch curve Φ_{b}(λ) of (A) PNPDA 5, (B) PNPDA 10, (C) PHDE, and (D) PNPDA 12.

FIG. 17. Leakage current density of PHDE and VHB 4905 (250% by 250% pre-strains).

FIG. 18. (A) Dielectric constants and (B) dielectric dissipation factors of PHDE and control DE materials.

FIG. 19. Schematic illustration of (A) blocked force and (B) energy density measurements setup (active area is 6 cm by 1 cm).

FIG. 20. (A) Blocked force of single layer PHDE films(40 μm thickness) under specified pre-loads. (B) Blocked force of single layer PHDE films at different frequencies. The driving voltage is 2.5 kV and the pre-load is 1.2 N.

FIG. 21. (A) Blocked force of single layer PHDE films tested in pure-shear mode with different concentration of PNPDA under 1.2 N pre-load. (B) Under 0.6 N pre-load.

FIG. 22. (A) Energy density of single layer PHDE films tested in pure-shear mode with different concentration of PNPDA tested with 100 g load. (B) Actuation strain of the films tested on a diaphragm.

FIG. 23. (A) Power outputs and (B) linear displacements of single layer PHDE films in life time tests.

FIG. 24. Photos captured during ball toss experiment, showing the ball on the PHDE actuator at (A) non-actuated and (B) actuated states.

FIG. 25. (A) Step-by-step depiction of mass and spring model replicating the jumping robot. (B) Heat map depicting jump height as a function of mass distribution. Color map units are in centimeters.

FIG. 26. Photos of a 4″ by 5″ 10-layer PHDE stack with 20 actuators.

FIG. 27. Swelling tests on stacks of 2 layers of identical DE films.

FIG. 28. (A) Stress-strain curves of single layer PHDE and 10-layer PHDE dry stack. (B) Storage modulus and tan δ of 10-layer PHDE dry stack at different frequencies.

FIG. 29. Static actuation of PHDE actuators with 20 μm thickness. The inset shows the pictures of a typical film before and after actuation

FIG. 30. (A) Photograph of a 10-layer PHDE stack fabricated in one batch with 20 areas, and (B) the number of the stacked actuators with different maximum driving voltages.

FIG. 31. (A) Diagram of “dry stacking” for dry stacking of PHDE stacks. (B) Photos of a 30-layer PHDE stack with five actuators.

FIG. 32. (A) Blocked force and energy density of 10-layer PHDE stacks tested in pure-shear mode. (B) Blocked force of 10-layer PHDE stacks tested in pure-shear mode at different frequencies. The driving voltage is 2.5 kV and the pre-load is 12 N. (C) Energy density of 10-layer PHDE stacks at different frequencies. The driving voltage is 2.5 kV and the load is 1000 g. (D) Average power density of 10-layer PHDE stacks tested in pure-shear mode with 1000 g load at 2.5 kV.

FIG. 33. (A) Linear strain and blocked force of PHDE roll actuators at different driving voltages (B) Linear strain of PHDE roll actuators at different driving frequencies at 2.5 kV. (C) A PHDE roll actuator lifts 100 g load at 5 Hz.

FIG. 34. A PHDE roll actuator as it is (A) bent, (B) twisted, and (C) hammered, the PHDE roll can still (D) be actuated normally.

FIG. 35. Water flow rates of a PHDE roll pump at different driving voltages and frequencies.

FIG. 36. A) DMA of three systems of near equal tensile strength and stress-strain relationship.

FIG. 37. Static actuation of three systems vs applied electric field

FIG. 38: Static actuation performance of single layer DEs with different monofunctional reactive diluents.

FIG. 39A Cross-sectional schematic of an actuator comprising dielectric elastomer.

FIG. 39B. Cross sectional schematic of multi-dielectric elastomer layer actuator.

FIG. 40. Flowchart illustrating a method of making a dielectric elastomer.

FIG. 41. Flowchart illustrating a method of making an actuator.

FIG. 42. Table S1

FIG. 43. Table S3.

FIG. 44. Table S4.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

The present disclosure reports on a dielectric elastomer comprising a crosslinked network comprising a poly(propylene oxide) unit on a network chain or a pendant group. As used herein, propylene oxide unit or poly(propylene oxide) unit refers to: —O—(C₃H₆O)ₙ— where n is any integer greater or equal to 1 (e.g., 1, 2, 3, etc.). Example compositions and characterizations are provided in the following sections.

### Example Dielectric Elastomer

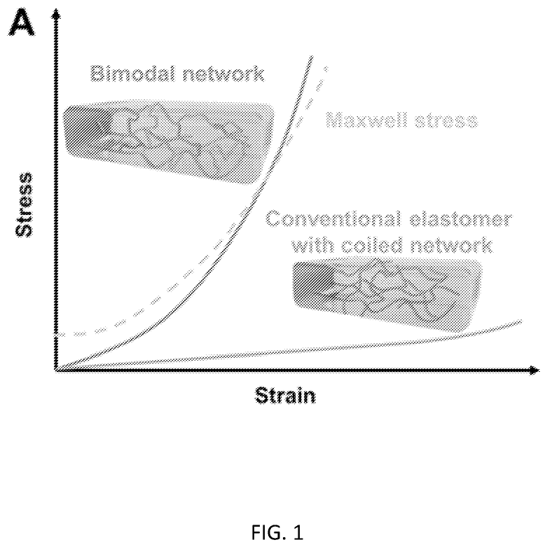

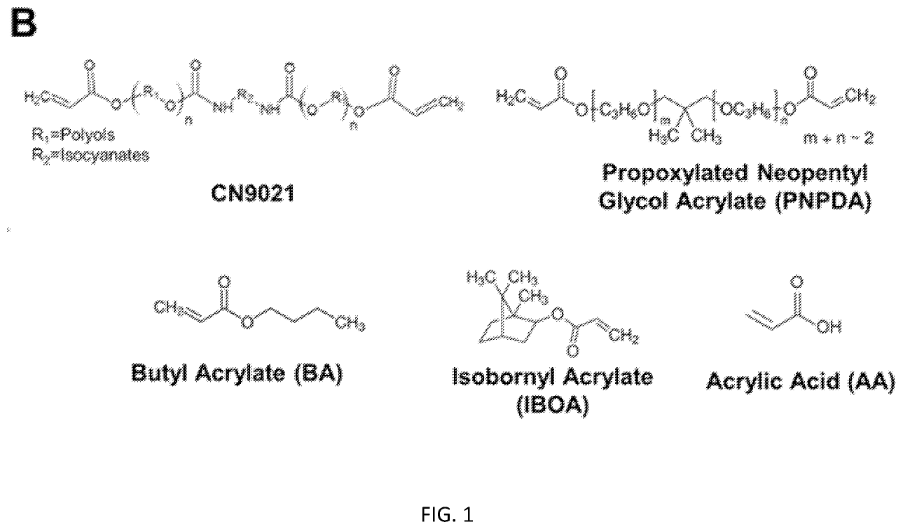

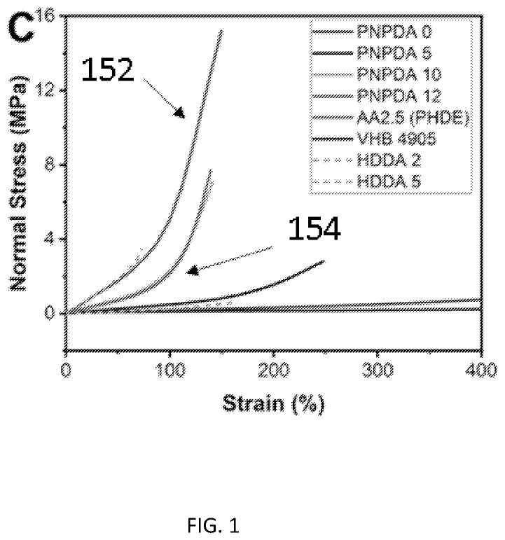

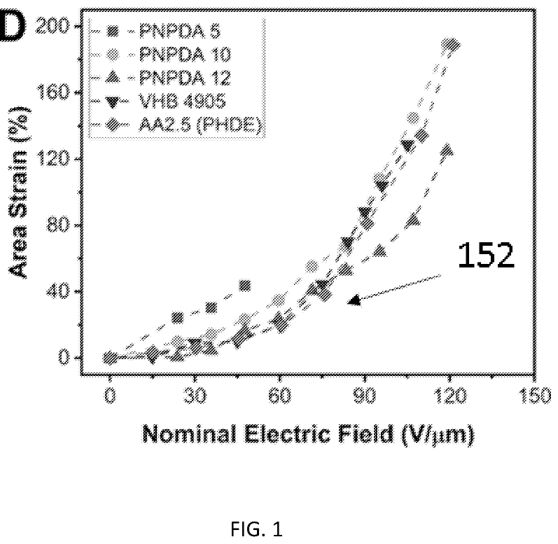

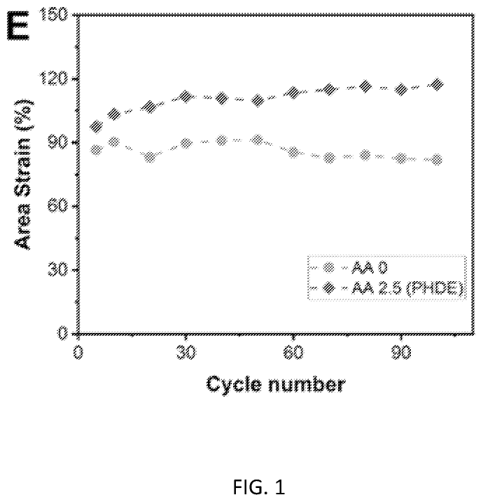

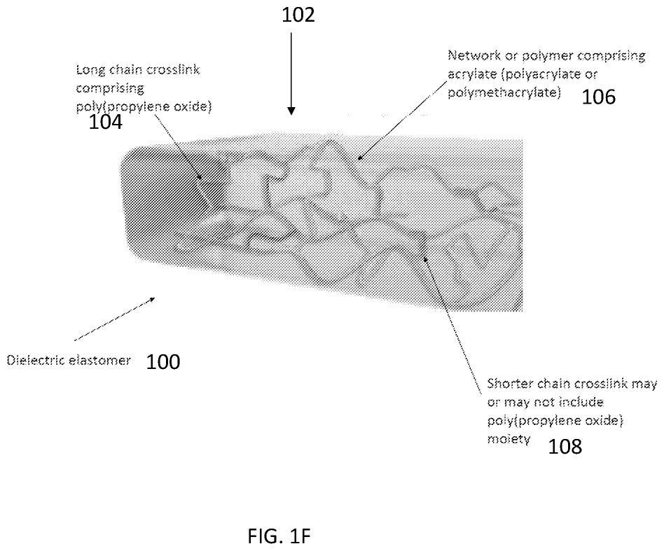

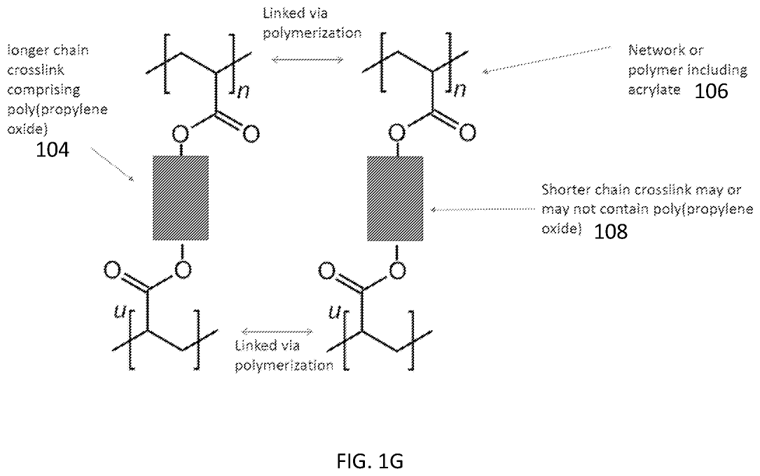

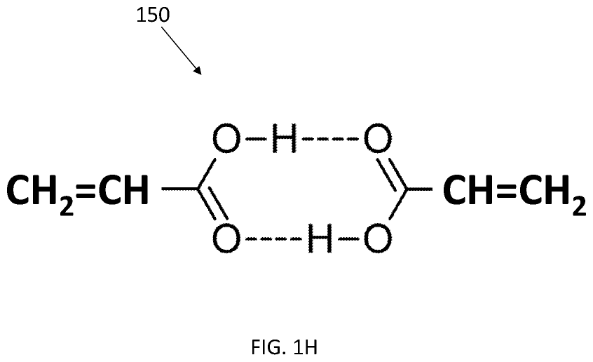

A dielectric elastomer film with a bimodal network structure was fabricated via solution processing in which reactants were mixed into one solution and films were cast and cured via ultraviolet light. The films can be casted by various methods including, but not limited to, spin coating, blade coating, bar coating, etc. on different substrates including, but not limited to, glasses, PET films, Kapton films, etc. The long chain segment in the bimodal network structure ensures large elongation and the second relatively short chain segment raises the modulus at modest strains to resist the rapid increases in Maxwell stress during actuation and suppress EMI (FIG. 1)(18, 36). FIG. 1B shows the molecular structures of reactants. Detailed formulations and nomenclature of samples can be found in Table S1.

Butyl acrylate (BA) and isobornyl acrylate (IBOA) were selected as co-monomers to lower the modulus and improve the toughness of co-polymers, respectively(37, 38). These reactive diluents were also important to reduce the viscosity of pre-polymer solutions(39). CN9021, a urethane diacrylate (UDA) with a high molecular weight, was selected as the flexible long-chain crosslinker and propoxylated neopentyl glycol diacrylate (PNPDA) was used as the short-chain crosslinker (FIG. 5). 2,2-dimethoxy-2-phenylacetophenone (DMPA) and benzophenone (BP) were used as co-photoinitiators to ensure complete curing through the bulk and the surface of the film.

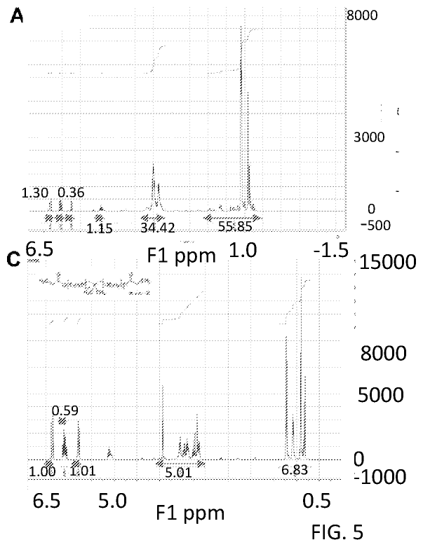

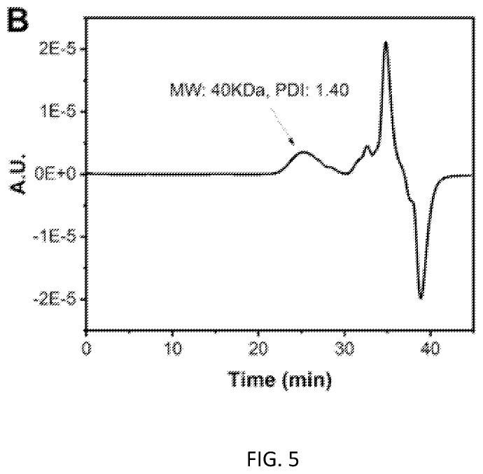

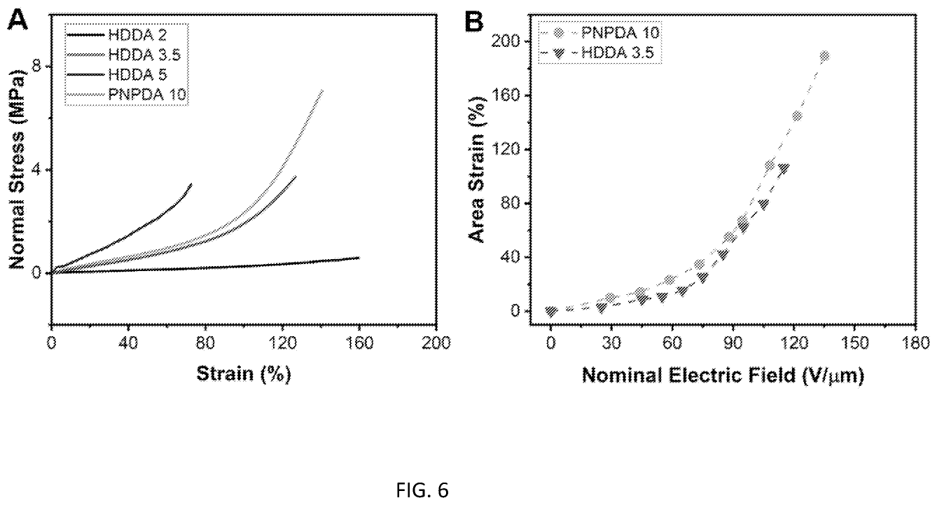

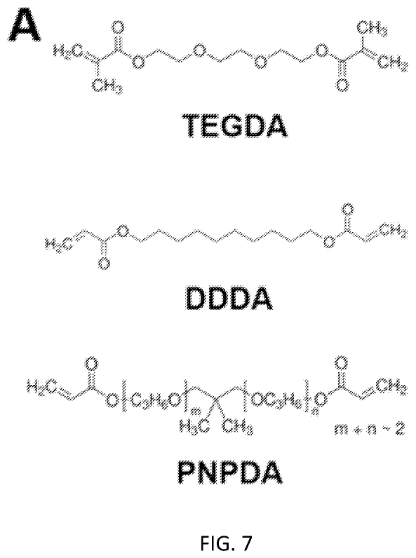

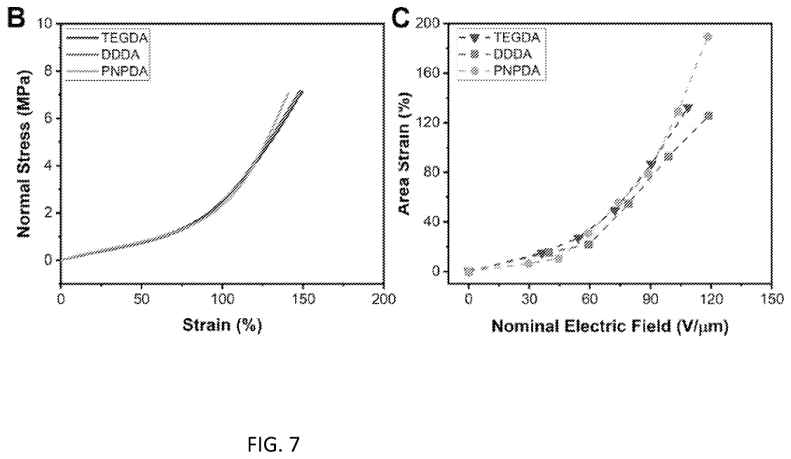

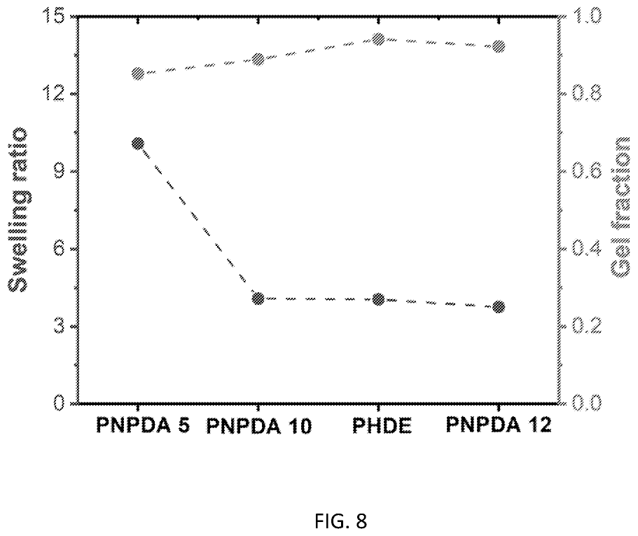

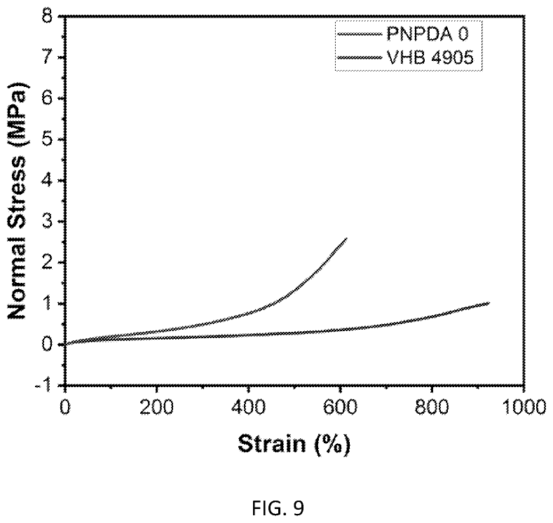

To achieve large and fast actuation, we developed two synthetic strategies to tune the bimodal system's stress-strain responses and viscoelastic property. Firstly, we proved the vital role of short-chain crosslinker in the bimodal network. Other explored molecules such as hexanediol diacrylate (HDDA) had short and stiff molecular backbones, which led to limited tunability of the stress-strain responses and low tensile strength (FIG. 1C and FIG. 6)(18). By adopting crosslinkers with softer and more extended chains, we achieved more tunable mechanical properties with high stretchability and tensile strength which were critical for high actuation performance (FIG. 7). We further controlled the crosslink density/gel fraction (FIG. 8), as well as the stress-strain responses by changing the concentrations of the short-chain crosslinker (FIG. 1C)(18). Before the short-chain crosslinker, PNPDA, is added, the DE shows a similar stress-strain relationship to non-prestretched VHB with a long stress-strain plateau (FIG. 9)(4, 16). With the bimodal network structure, our DEs stiffen after a critical stretch ratio because the non-crystallizable elastomer is driven into its non-Gaussian region and starts to have stress redistribution(40), which can suppress EMI and improve its actuation stability. This critical stretch ratio shifts to a smaller value and the stiffening becomes more significant as the crosslink density increases.

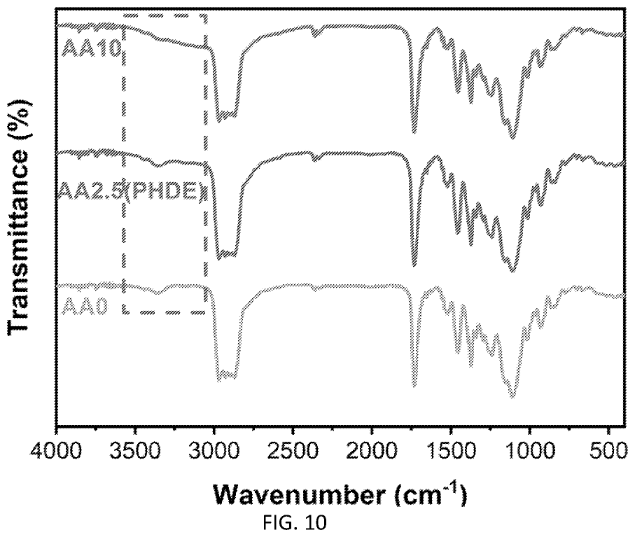

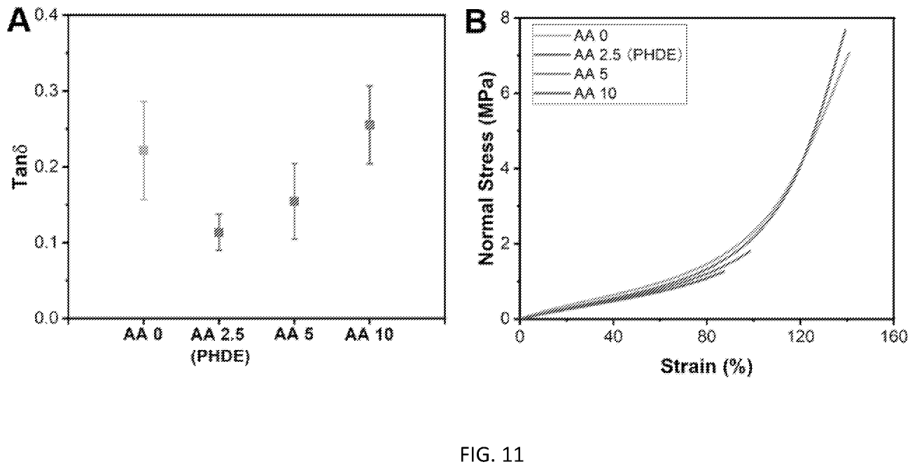

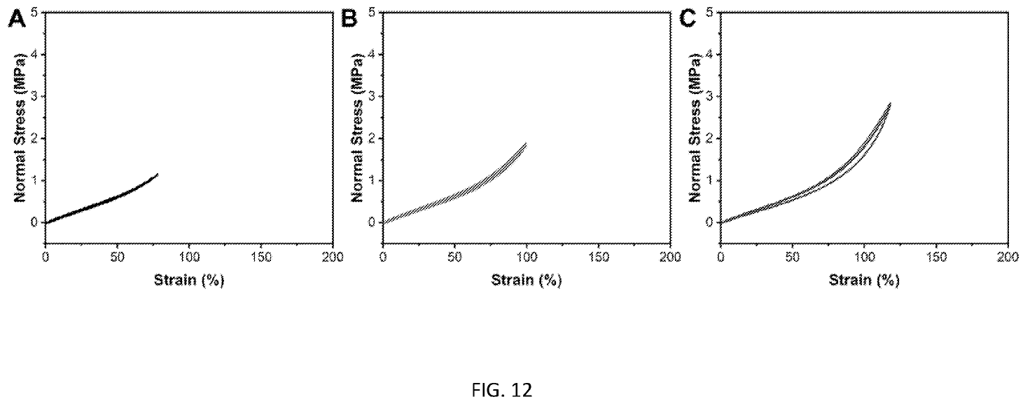

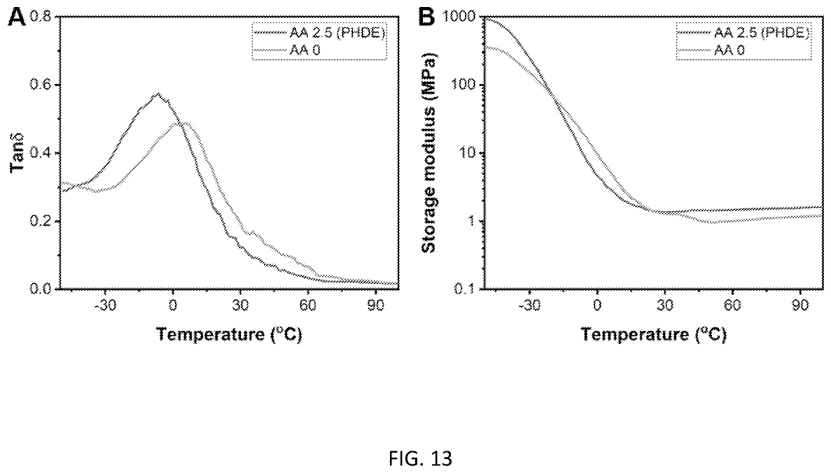

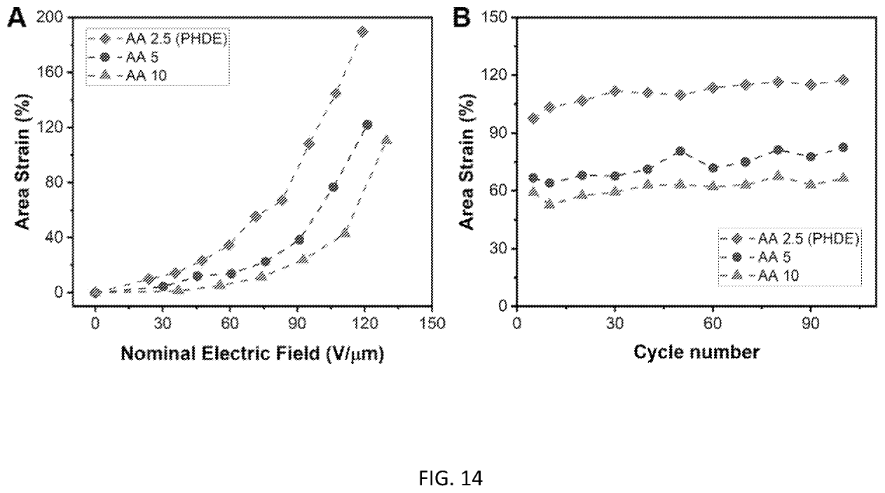

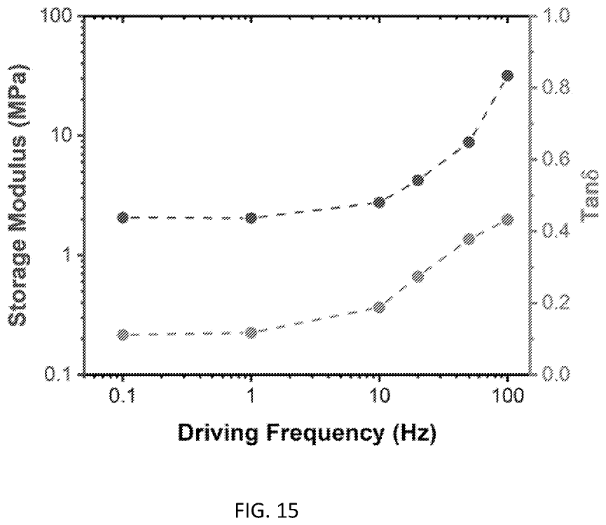

We then explored the incorporation of additional hydrogen bonds in the DE network to modify the viscoelasticity while maintaining its stress-strain relationship. The high viscoelastic loss has been a critical issue for acrylic based DE. Conventionally, a large amount of plasticizer (20-30 wt %) is added (18), but it significantly alters the stress-strain response. We added an acrylic acid (AA) co-monomer in our new DEs, which provides side groups to form two-point hydrogen bonded dimers with themselves, as well as with the —NH— groups on the CN9021 and PNPDA crosslinkers (FIG. 10)(41-43). When a small amount of AA (e.g., 2.5 parts of weight) is added, the mechanical loss factor of DE, a measurement of the viscoelasticity, decreased from ˜0.22 to ˜0.11 at room temperature and low frequencies (FIG. 11). Crucially, the stress-strain curve of DE is almost unchanged (FIG. 1C) and the strain stiffening effect is preserved as indicated by the elastic modulus at different strain levels (Table S2). Cyclic tensile tests further demonstrate that the DE shows high elasticity and mechanical stability (FIG. 12). The reduced viscoelasticity can be attributed to the hydrogen bonds which act as weak, physical crosslinks and can dynamically dissociate, leading to lower glass transition temperature (T_{g}) (FIG. 13) and higher chain mobility in the network(44). As more AA is added, hydrogen bonds become highly concentrated (FIG. 11), resulting in inhibited actuation performance (FIG. 14). We also noticed that when the frequency is above 20 Hz, the storage modulus and loss factor increase rapidly (FIG. 15).

### Example Actuation Performance

The static actuation performance of the example dielectric elastomer described above was tested in a diaphragm configuration (FIG. 1D)(45). A moderate ratio of short-chain crosslinker to long-chain one was found to be ideal for high actuation strains. When 5 wt % of PNPDA was used, the DE performed poorly due to premature actuation failure at 1.5 kV. In contrast, the DE with 12 wt % of PNPDA showed a greater stiffening effect and its maximum strain was limited to 124% area strain. The DE with 10 wt % of PNPDA exhibited the best actuation performance with a maximum strain of 189%. This high actuation strain was well maintained after AA was added. The DE with 2.5 part of AA showed no snap-through during its actuation, indicating that EMI was fully suppressed without prestretching, which was also confirmed by modeling studies (FIG. 16). Its reduced viscoelasticity enabled higher actuation strains at high actuation speeds, which is superior to other DE materials (Table S3). Under a square wave voltage input with frequency of 2 Hz, the DE with AA exhibited an average actuation of 110% area strain over 100 cycles, whereas the DE without AA only had an average of 70% strain (FIG. 1E). Thus, the DE with 10 wt % of PNPDA and an additional 2.5 parts of AA is finalized as the PHDE composition for film preparation and device fabrication.

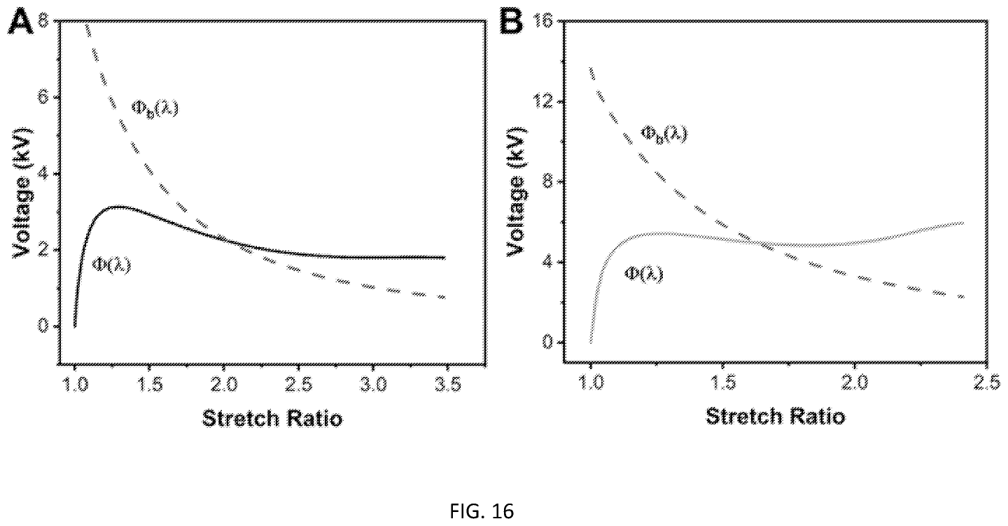

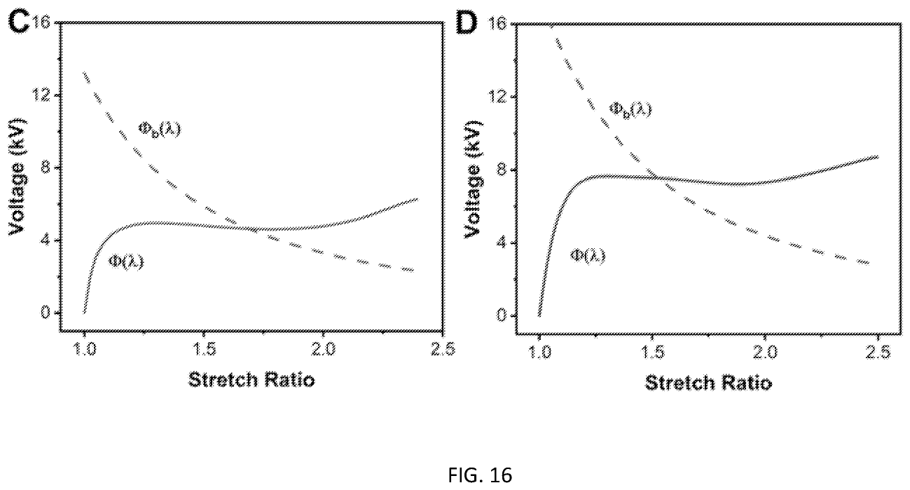

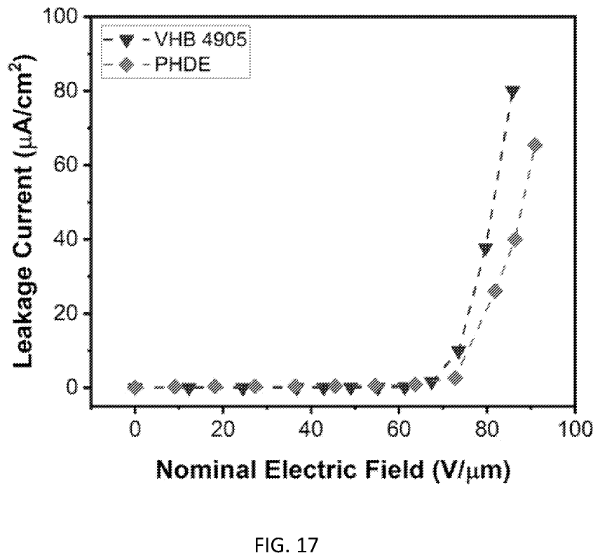

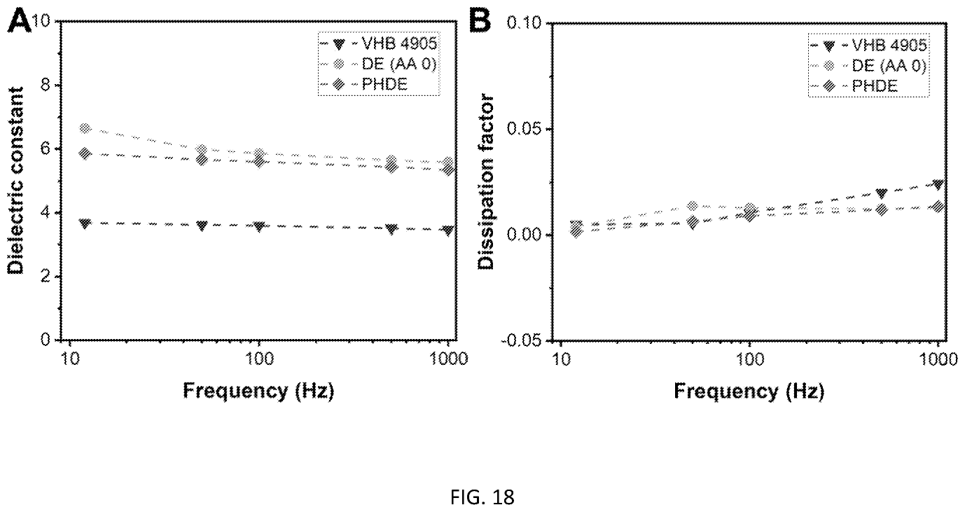

PHDE also showed high dielectric strength with an apparent electrical breakdown field of 330 V/μm, low leakage currents (FIG. 17), a high dielectric constant of 5.35 and a small dielectric dissipation factor of 0.014 at 1 k Hz (FIG. 18).

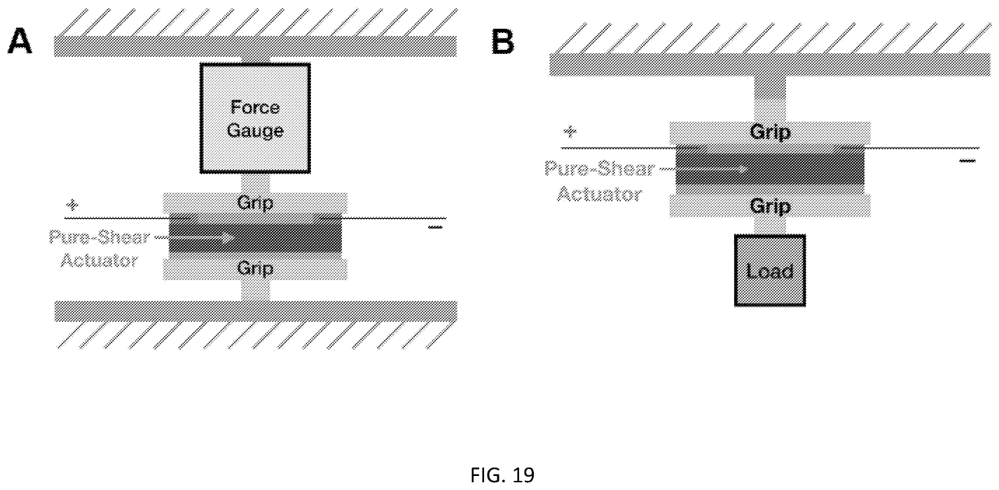

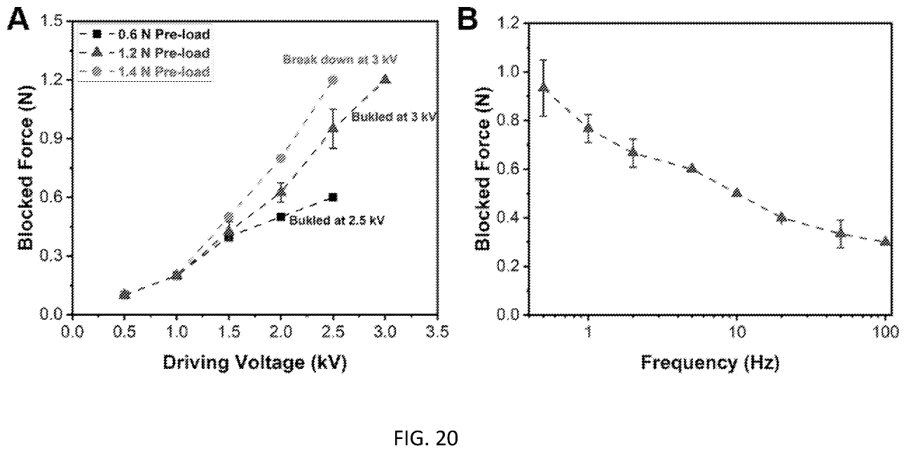

To measure the force output and energy density of the PHDE, we tested the films in a pure-shear mode(45-48). The set-ups for both measurements are shown in FIG. 19. The single layer PHDE film measured 6 cm by 1 cm by 40 μm and ˜0.030 g of active material. Under preloaded isometric conditions(37), the single layer PHDE was able to output a stable force of ˜0.95 N (˜0.40 MPa stress) at 2.5 kV with a 1.2 N pre-load (FIG. 20A). The force maintained ˜0.67 N (29% reduction) at 2 Hz and ˜0.4 N at 20 Hz (FIG. 20B). Note that the reduced maximum driving voltage was caused by a decrease in film thickness under heavy loads. Compared to other high force outputting DE devices(49), this high force was achieved without prestretching.

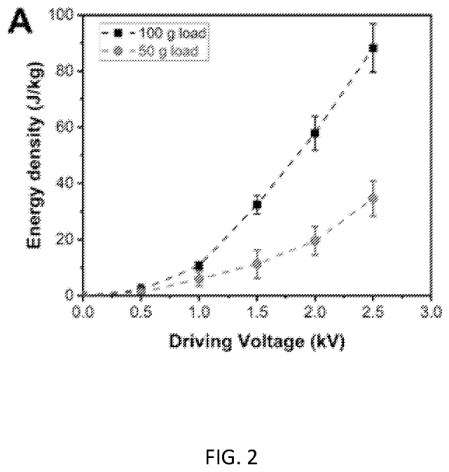

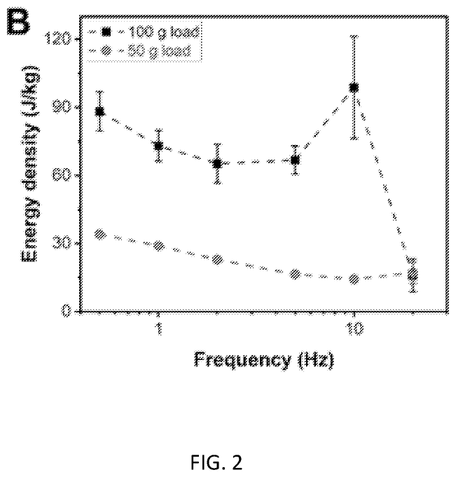

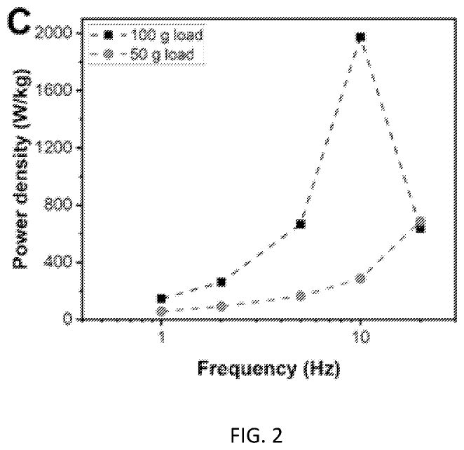

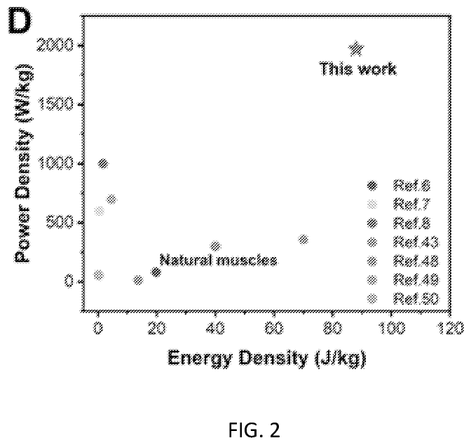

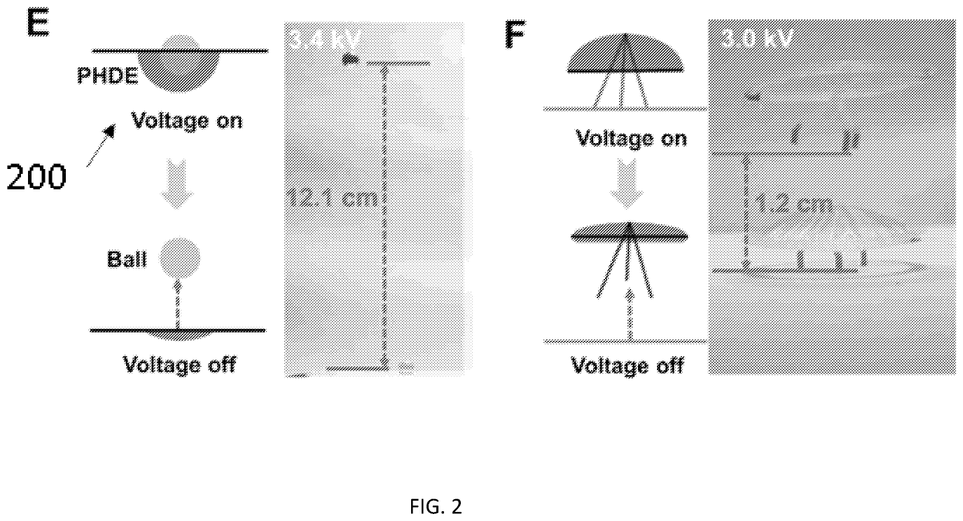

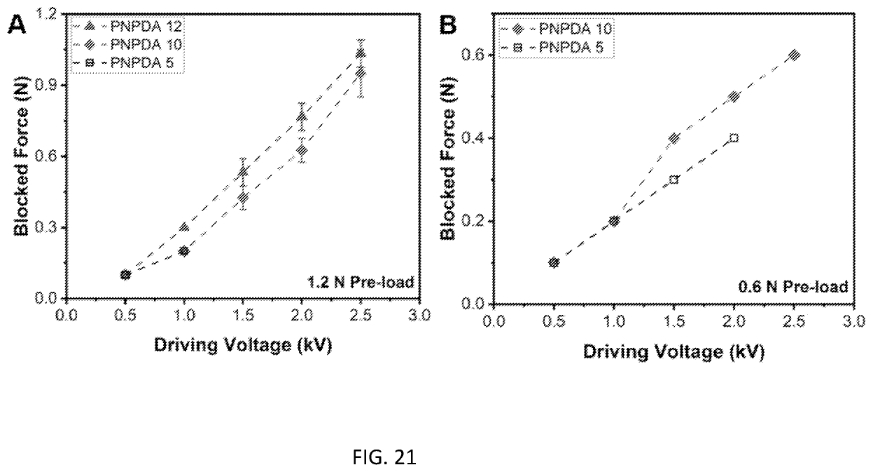

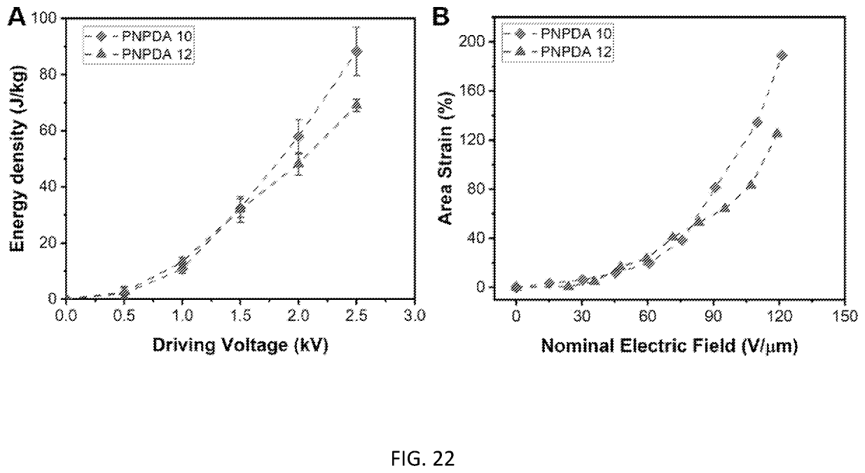

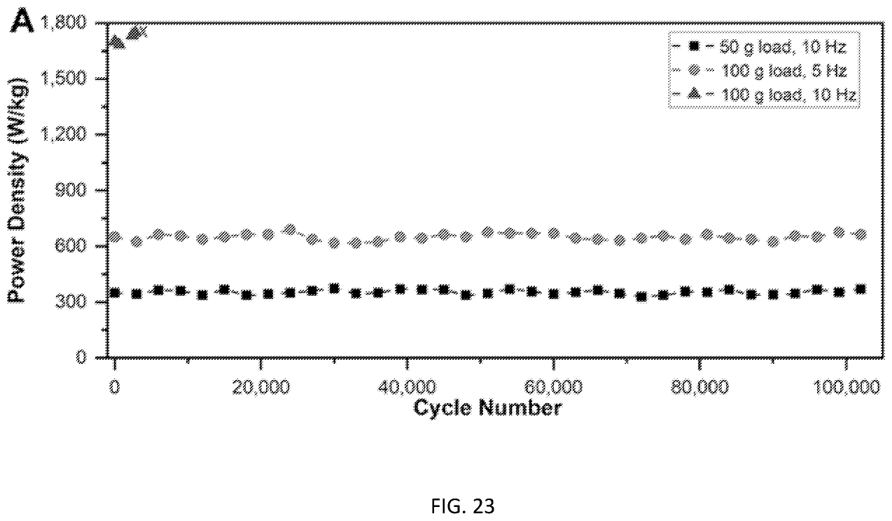

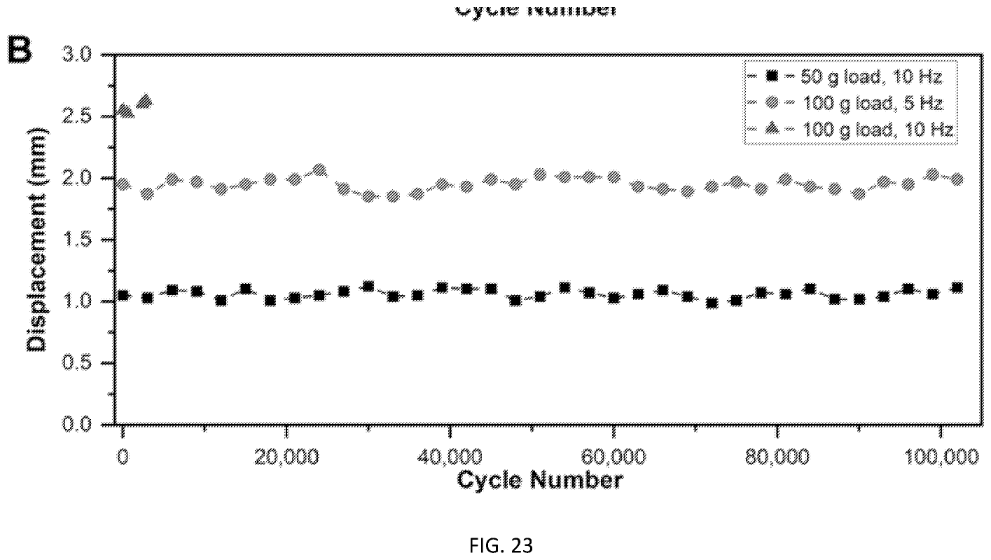

Under isotonic conditions, the single layer PHDE films performed a specific work of ˜35 J/kg with a 50 g load and ˜88 J/kg with a 100 g load during contraction (the contraction step is half of a complete actuation cycle) at 2.5 kV (FIG. 2A). This maximum energy density is more than twice than that of natural muscles (0.4 to 40 J/kg) and far exceeds the previous record value (19.8 J/kg) of DEAs reported by Duduta et al(6). With 50 g load, the PHDE maintained energy densities of ˜16 J/kg and ˜17 J/kg at 5 Hz and 20 Hz, respectively (FIG. 2B). With 100 g load, the PHDE films exhibited energy densities of ˜67 J/kg at 5 Hz and ˜16 J/kg at 20 Hz (FIG. 2B and Movie S2) and the corresponding power densities were calculated to be ˜670 W/kg at 5 Hz and ˜640 W/kg at 20 Hz (FIG. 2C(47). The peak energy density of ˜99 J/kg and corresponding power density of ˜1970 W/kg at 10 Hz was caused by resonant responses of planar actuator systems(47, 50). These power densities are about one order of magnitude higher than those of natural muscles(51), and can be achieved in the 101 Hz range or lower, which is desirable for many soft actuation systems perceived for DEAs. At frequencies greater than or equal to 50 Hz, the films showed negligible linear strain and was not able to effectively perform work. In addition, the blocked force and energy density of bimodal networked DEs can be tuned by adjusting the concentration of short-chain crosslinkers for different applications (FIGS. 21 and 22). More importantly, the PHDE exhibited high stability when performing work (FIG. 23).

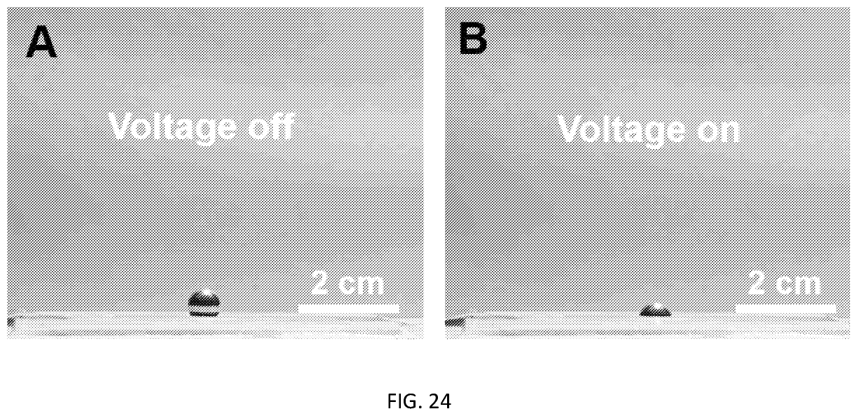

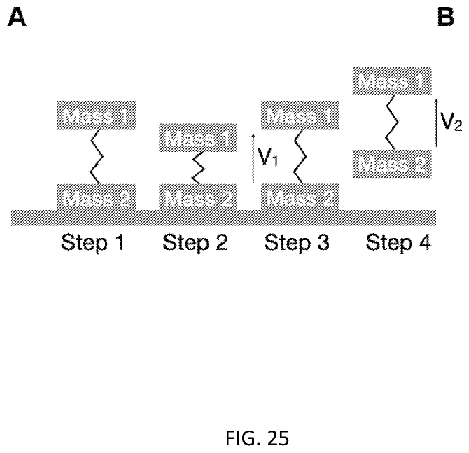

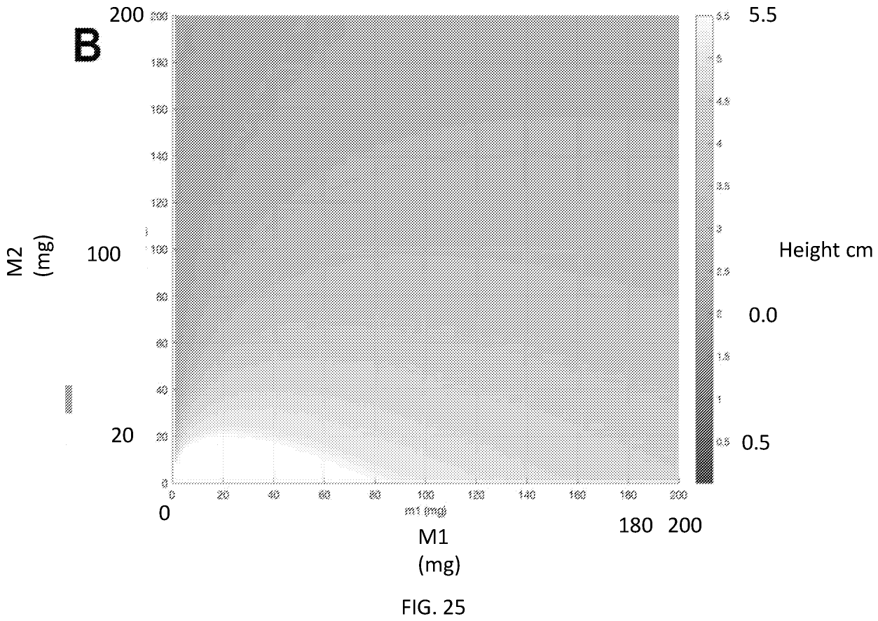

The maximum energy and power output densities of PHDE are superior to those of natural muscles and DEAs developed in recent years (FIG. 2D)(6-8, 47, 52-54). Therefore, PHDE can perform jobs that were not feasible with other DE materials, as shown in the following two applications. Owing to its large and fast actuation, the PHDE film was able to toss an aluminum ball, which is 20 times heavier than itself, to 12.1 cm high (FIG. 2E), reaching an energy transfer efficiency of ˜10% (FIG. 24). Secondly, a miniature jumping robot using a single layer PHDE actuator was shown to achieve a height of 1.2 cm, which was ˜67% of the theoretical height of this jumping system (FIG. 2F). The PHDE film was seamlessly incorporated into a robotic framework without prestretching and demonstrated its capacity as a light-weight, energy-dense actuator as the entire robot weighed less than 165 mg (FIG. 25).

### Example Multilayer Actuators

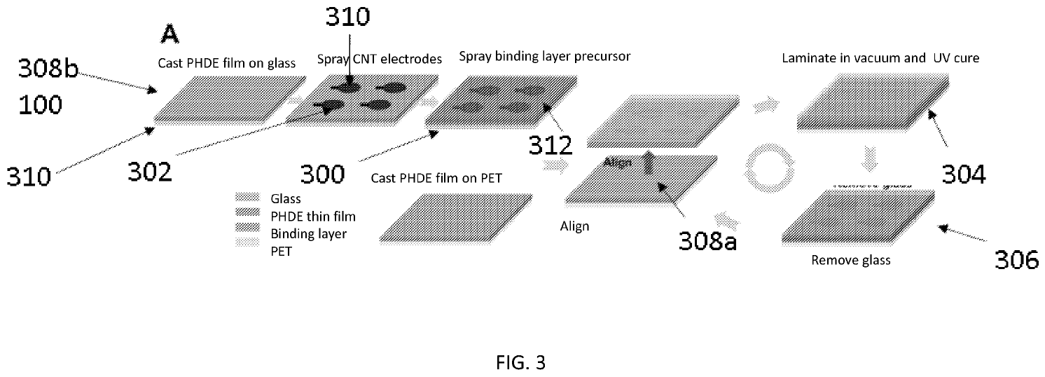

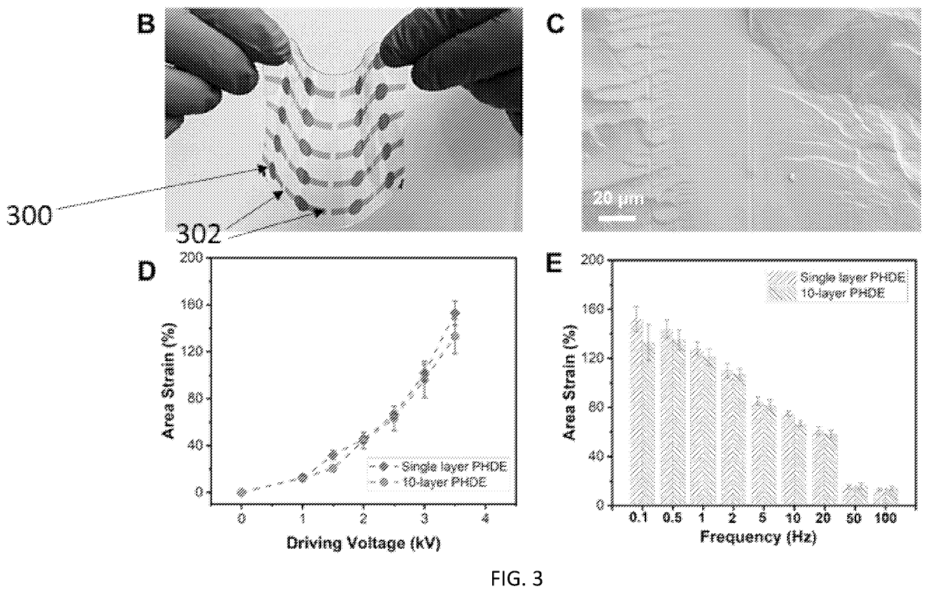

To scale up the energy and power outputs of DEAs at low voltages, we developed a novel dry stacking method to fabricate multilayer DEAs. This method was demonstrated with PHDE, but can be used with other polymer thin films, including pre-formed DE films. As illustrated in FIG. 3A, to fabricate an N-layer PHDE stack, N−1 PHDE films are cast on glass substrates and 1 film is prepared on PET. The blade coated films have a uniform thickness of ˜40 μm. CNT electrodes and a thin layer of uncured acrylic polymer precursor acting as a binding layer are sprayed on the glass/PHDE films. The PET/PHDE is aligned onto a glass/PHDE/CNT/precursor and laminated in a vacuum laminator. After UV curing the precursor layer, the glass is removed and the 2-layer PHDE stack, which is now on PET, is aligned onto another glass/PHDE/CNT/precursor to add the third PHDE layer. These processes are repeated until an N-layer PHDE stack is fabricated.

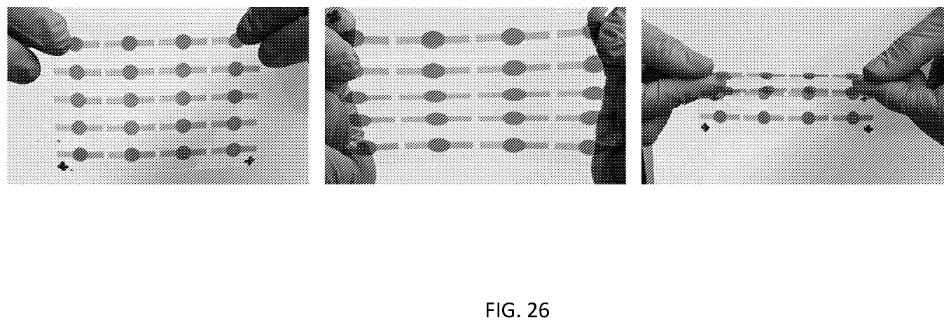

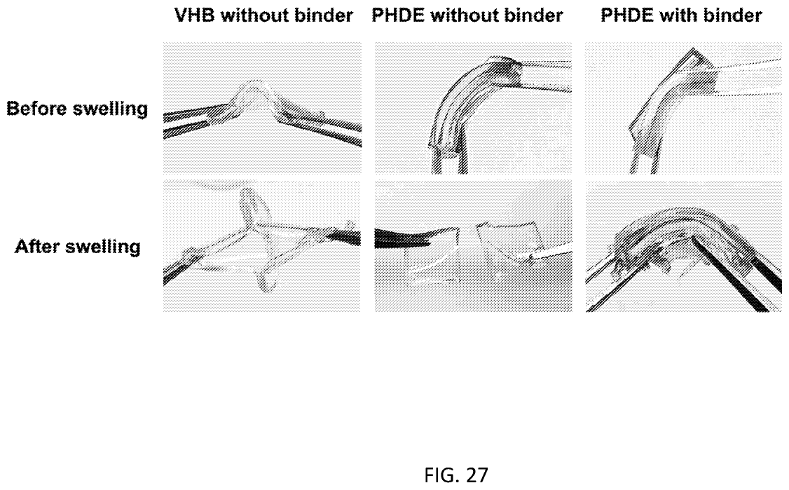

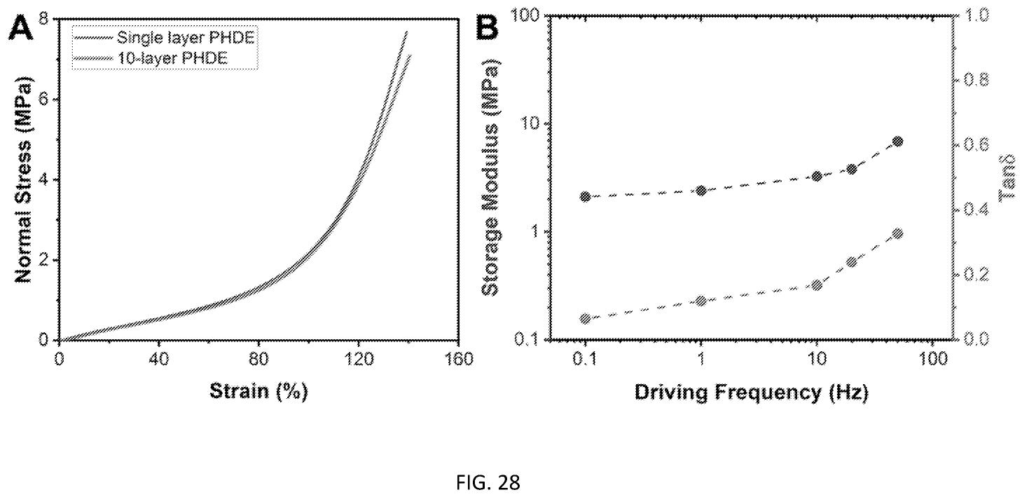

FIGS. 3B and 26 show the picture of a 10-layer PHDE stack with an array of 20 actuators. The cross-section of a PHDE stack was examined by scanning electron microscopy (SEM) and the image in FIG. 3C shows uniform thickness of PHDE layers and solid sealing between layers due to the thin binding layer. The strong bonding was proved by a swelling test (FIG. 27) and the facts that the stress-strain curve and dynamic moduli of a 10-layer PHDE stack are very close to those of a single layer film (FIG. 28). The dielectric constant of a 10-layer PHDE stack is measured to be 5.37 at 1 k Hz and its dissipation factor increases to 0.020 at 1 k Hz, possibly due to the dielectric loss at interfaces.

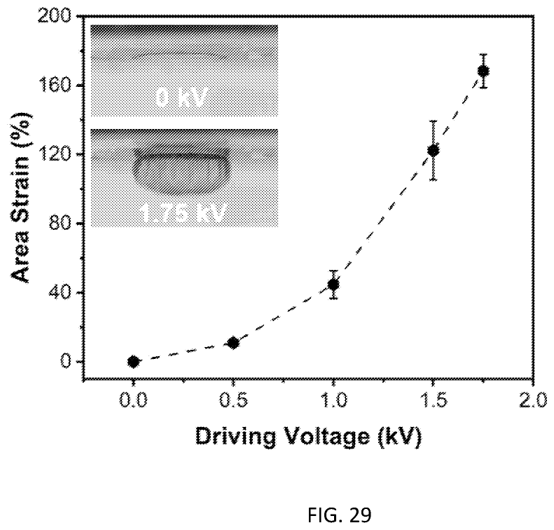

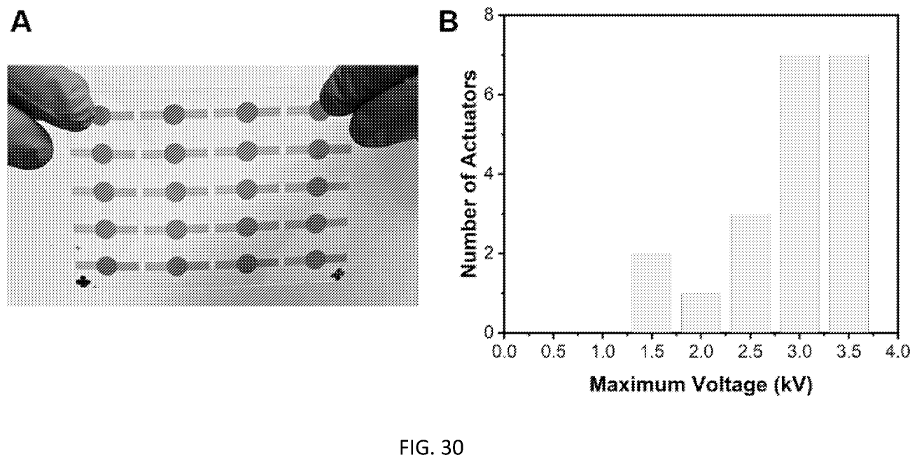

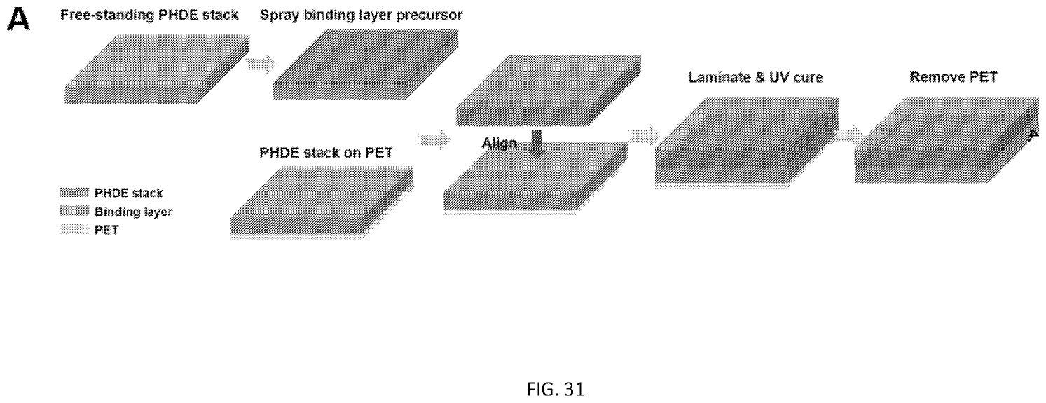

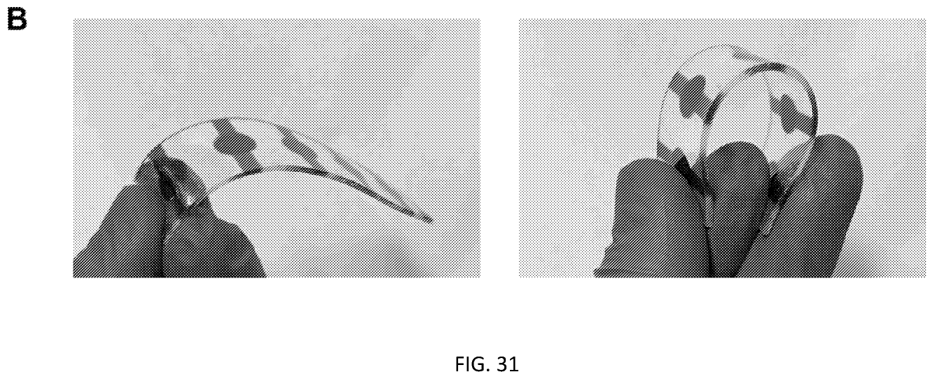

Compared to traditional “wet stacking” methods, (6, 21, 22, 55), our dry stacking method for PHDE shows many advantageous features. It is compatible with established large-scale materials processing techniques such as slot die coating or even roll-to-roll fabrication, and the film dimensions and thickness can be easily tuned (FIG. 29). Additionally, this method minimizes defects by screening individual films prior to stacking, and results in a high yield (FIG. 30). Since large-area film casting/curing, electrode deposition, and film lamination can be conducted in parallel, the process is very efficient. Fabricated PHDE stacks can also be modularly stacked on each other. For example, 10-layer PHDE stacks can be stacked together via “dry stacking” to form tens of layers of stacks (FIG. 31).

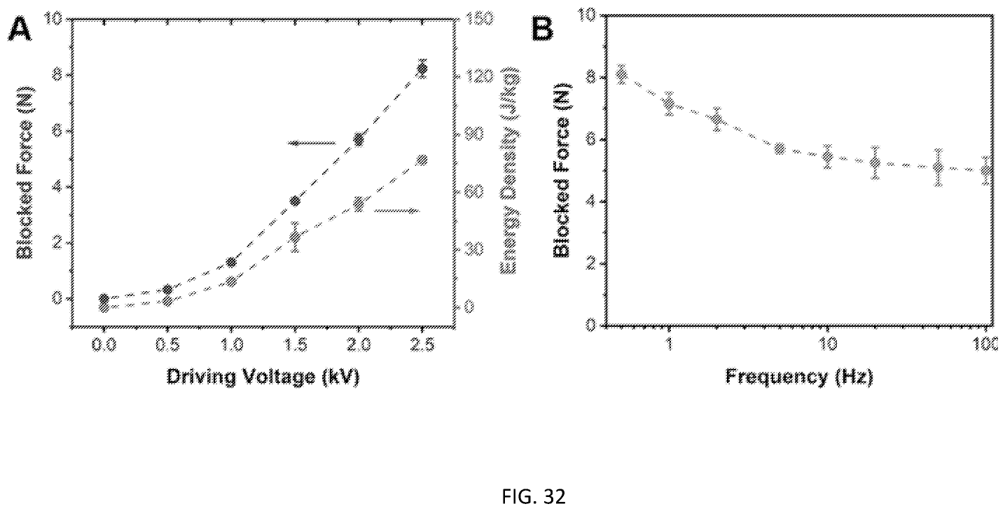

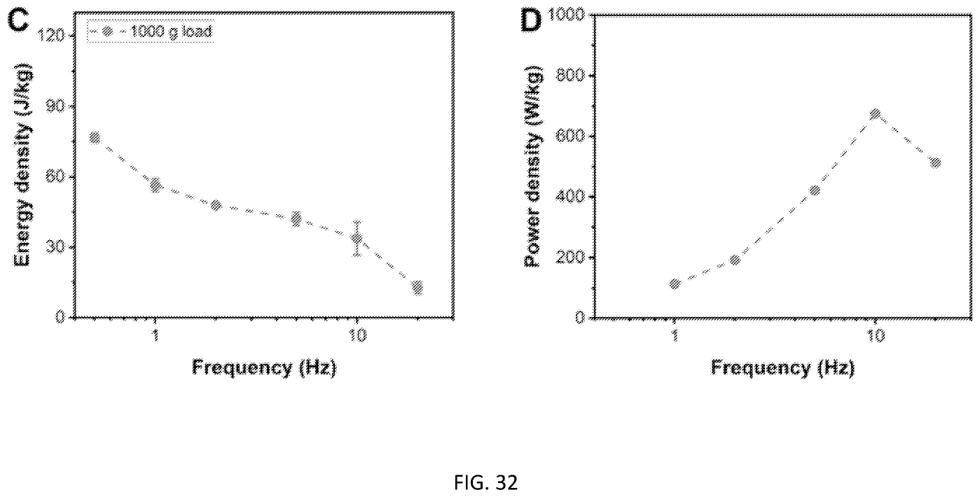

The actuation strain of 10-layer PHDE actuators is comparable to that of single layer actuators at the same low driving voltages (FIG. 3D). The strain is slightly lower at higher voltages, possibly due to greater stiffness from the inactive border surrounding the 10-layer actuators. In the stacking, carbon nanotubes (CNT) were used as compliant electrodes and they could cause lower maximum strains due to decreased conductivity at highly stretched states. Moreover, the multilayer actuator showed comparable response speed to single layer films. Both single layer and 10-layer PHDE actuators reached strains above 110% at 2 Hz and maintained strains of ˜60% at 20 Hz (FIG. 3E). Viscoelastic losses limit performance at frequencies higher than 50 Hz, but could possibly be reduced by introducing flexible side chains (16, 17), or adding proper amounts of plasticizers in the network to promote the chain mobility(18). In addition, our “dry stacking” method can also linearly scale up the force, energy, and power outputs with the number of layers and experiences less than a 20% reduction in energy and power densities (FIG. 32).

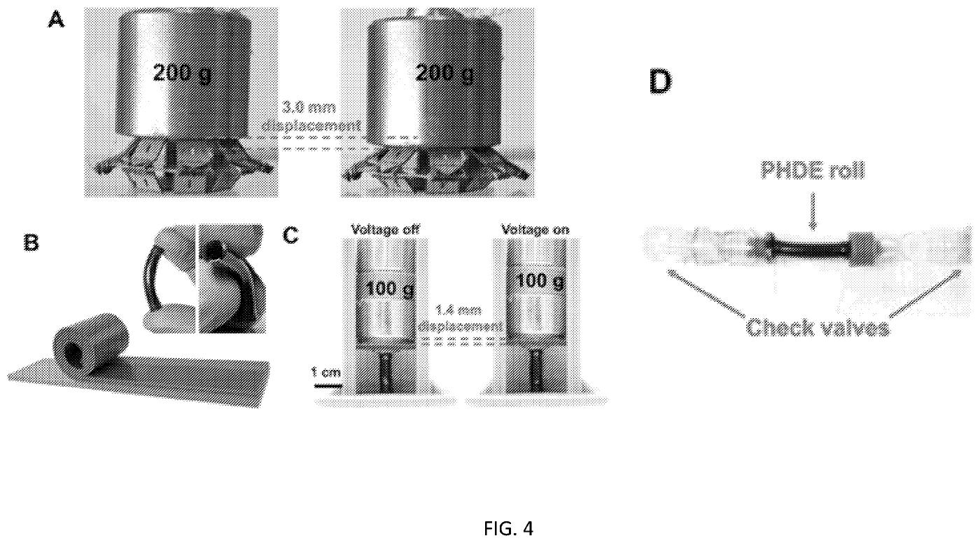

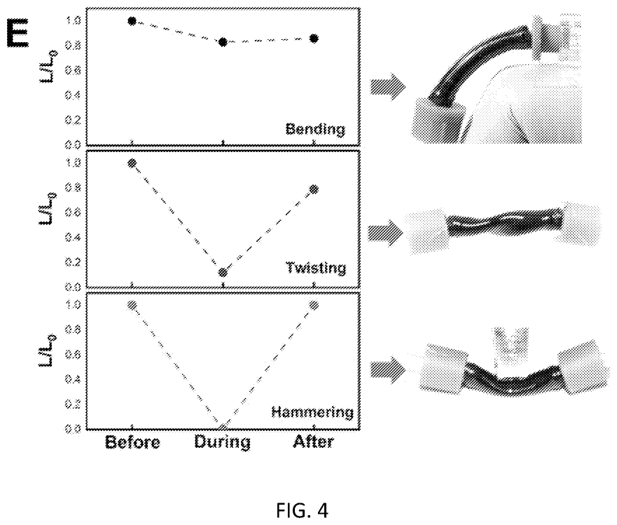

The “dry stacking” fabrication method, along with the highly tunable and processable PHDE, enables new avenues for DEA devices and performance improvements. As an example, we fabricated “spider” actuators, which were identified as a potential DEA design(56), but never realized, in part, because they are not compatible with high prestretching. The basic concept uses radially symmetric inclined “legs” to couple axial force to radial loading of a circle of DE film. The leg angle relative to the film changes during actuation, giving the linkage nonlinear mechanical advantage that can be tuned to maximize performance. We built one instantiation of this linkage, tuned for high axial force, and tested it with 4-layer PHDE stacks with an active area of ˜4.8 cm². As shown in FIG. 4A, we demonstrated a PHDE based spider actuator which successfully lifted a 200 g load with ˜3.0 mm linear displacement at 2.5 kV. The specific work based on the mass of active PHDE was calculated to be ˜74 J/kg. One of the main benefits of this type of architecture is that it can dramatically increase the overall actuator stroke. Spider structures can theoretically be stacked in series to produce high force and very high displacement actuator systems.

### Example Roll Actuators

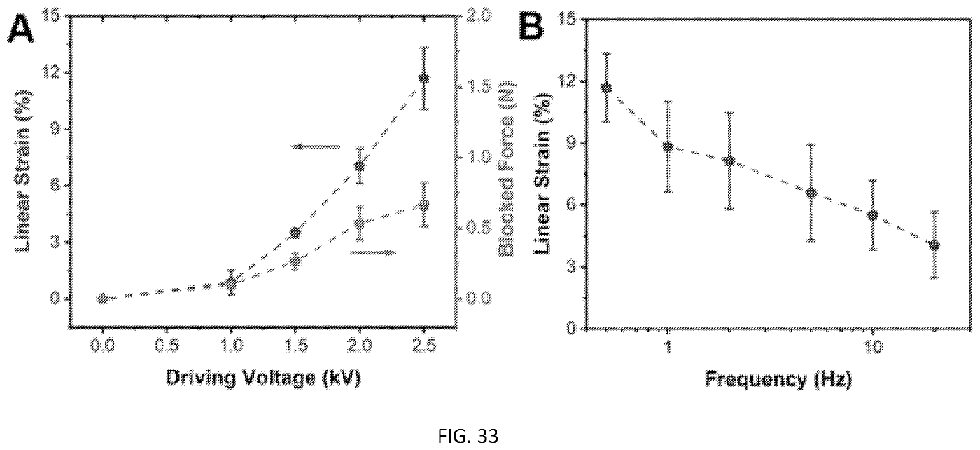

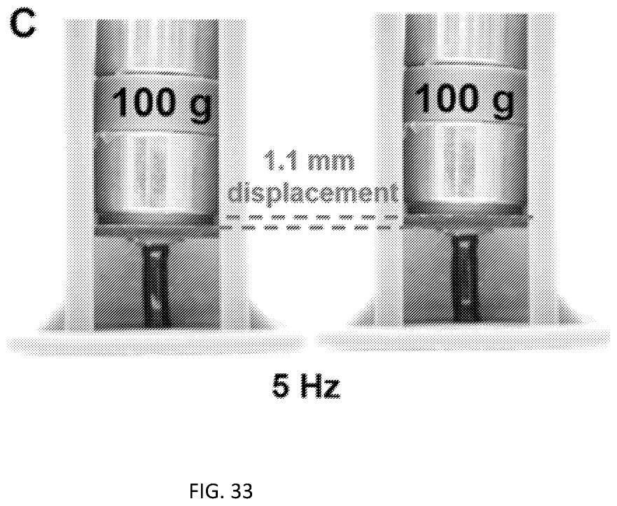

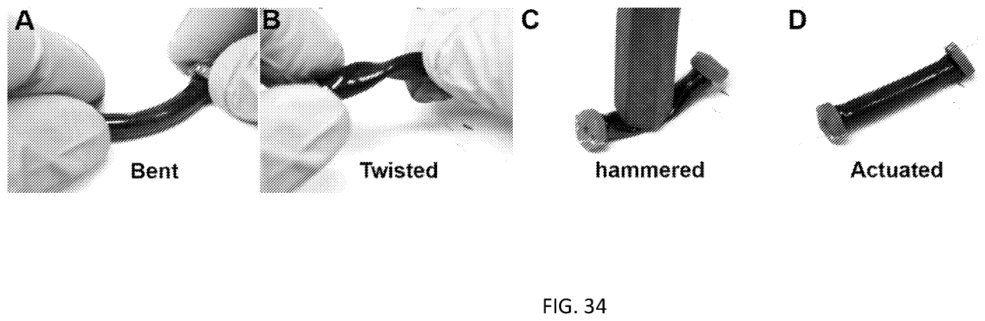

We also designed all-polymer multifunctional roll actuators to demonstrate the high processability of multilayer PHDE films and the flexibility in device design it yields. As shown in FIG. 4B, a 2-layer PHDE strip was fabricated via our “dry stacking” method and then rolled into a free standing tube with an inner diameter of ˜3 mm. There are 11 rounds of the 2-layer stack in the roll, with inner-most and outer rounds acting as insulation, leading to a total of ˜18 active layers in the roll. A PHDE roll was characterized as a linear actuator (FIG. 33) and was able to lift a 100 g load by 1.4 mm at 0.5 Hz, which translated to an output energy density of 15.6 J/kg based on the active material mass (FIG. 4C). The displacement at 5 Hz was 1.1 mm (FIG. 33C), with a power density calculated to be 122 W/kg. These values are lower than those determined in the pure-shear mode and the spider actuators, possibly because the inactive layers restrict its linear strain and the circumferential strain is not coupled. However, the roll is made entirely of polymers (except for a small amount of conductive materials), and it is compact, lightweight, and does not use any supporting structures which add additional weight and volume(49, 57). Moreover, the PHDE rolls are highly robust and remain functional after they are bent, twisted, and hammered (FIG. 34 and Movie S8).

These PHDE actuators can drive various types of devices, such as peristaltic pumps, inchworm robots, flying robots(7), etc. To demonstrate this, we integrated two check valves to build a tubular pump from a PHDE roll (FIG. 4D). The flow rate (L) could be tuned by controlling the driving voltage and frequency. The peak flow rate reached ˜20.4 mL/min at 2.5 kV and 10 Hz, which translated to a specific flow rate of ˜100,000 mL/min-kg (FIG. S31 and Movie S9). This value is about two orders of magnitude higher than that of a high-performance miniature pump (TCS Micropumps, MGD 1000S(58). These PHDE roll pumps also have high flexibility and an overall robust nature. FIG. 4E shows the pump operating at a 90° bend angle. Once straightened, the pump recovered and output at a flowrate that was ˜90% of the initial flow rate. A similar performance recovery was seen after the pump had been twisted and hammered during operation. Its tunable flow rate, compactness, light weight, low noise, and high mechanical compliancy make it a promising device for flexible medical implants and soft robotics.

### Possible Modifications and Variations

The present disclosure demonstrates that PHDE synthesis enables rational design of new dielectric elastomers with mechanical and actuation properties tailored to meet specific application needs. The synthetic strategies developed in this work can be also used to shape mechanical and dielectric properties of other polymeric materials. Combining the best of acrylic elastomers and silicones, our novel PHDE material enables realization of the full potential of DEs as artificial muscles as it achieved actuations strains over 110% at 2 Hz and a peak specific power density of ˜1970 W/kg. Our innovative dry stacking technique can enable various DE actuator structures for insect-size robots, haptic and wearable devices with limited loss of actuation performance. This method is also useful tool for processing other soft thin films for a wide range of applications, such as microfluidics, tissue engineering, microfabrication, etc.

### Materials and Methods Used to Manufacture and Characterize the Example Dielectric Elastomers

### Materials

Urethane diacrylate (UDA, catalog name: CN9021) and isobornyl acrylate (IBOA) were obtained from Sartomer Company and used as received. Butyl acrylate (BA), acrylic acid (AA), neopentyl glycol propoxylate diacrylate (PNPDA), isopropyl alcohol (IPA), poly(acrylic acid) solution (Mw-100,000, 35 wt % in H₂O), benzophenone (BP) and 2,2-dimethoxy-2-phenylacetophenone (DMPA) were purchased from Sigma Aldrich and used as received. Single-walled carbon nanotubes (SWCNTs, catalog name: P3-SWNT) were purchased from Carbon Solutions, Inc.

### Fabrication of Single Layer Bimodal Networked DE Films for General Testing

Each prepolymer solution was weighed out according to predetermined ratios and mixed overnight. To screen the formulation, the pre-polymer solution was spin coated onto a poly (acrylic acid) 5% solution (PAA) in IPA precoated glass substrate with 1000 rpm speed. The film thickness is dependent on the viscosity of pre-polymer solutions. PNPDA 5 samples have a thickness of ˜35 μm, PNPDA 10 samples have a thickness of ˜49 μm, and PNPDA 12 samples have a thickness of ˜53 μm. The PAA coating acts as a sacrificial layer. The prepolymer solution coated on the glass was then UV cured in air on a UV curing conveyor equipped with 2.5 W/cm² Fusion 300s type “h” UV curing bulb for 2 passes at a speed of 6 ft/min. The glass with the film still coated on it was affixed to an acrylic frame ( 1/16 in thick, 0.8 in ×2.5 in opening) with double-sided tape. The outside of the glass was also taped to the frame and submerged in a water bath. After 1 hour, the film peeled off the glass and left to dry for at least 1 hour. Once completely dry, the film was coated (cotton swab) on both sides of the film with a thin layer carbon grease (NyoGel 756G, Nye Lubricants) as compliant electrodes. To ensure consistent properties of PHDE films, the reactants were stirred overnight for full mixing and processing conditions are strictly controlled.

### Fabrication of Single Layer PHDE Films for Multilayer Actuators

Each prepolymer solution was weighed out according to wt % predetermined ratios and mixed overnight. The pre-polymer solution was then blade coated on a drawdown machine onto a glass substrate. The prepolymer solution coated on the glass was then UV cured in N₂ on a UV curing conveyor equipped with 2.5 W/cm² Fusion 300s type “h” UV curing bulb for 2 passes at a speed of 18 ft/min. N₂ atmosphere was used to avoid the thin layer of residue on film surface and increase its adhesion to CNT. The blade coated films have a uniform thickness of ˜40 μm. For single layer testing with CNT electrode, the glass was still coated with PAA as sacrificial layer and then with the film was affixed to an acrylic frame ( 1/16 in thick, 0.8 in ×2.5 in opening) with double-sided tape. The outside of the glass was also taped to the frame and submerged in a water bath. After 1 hour, the film was peeled off the glass and left to dry for at least 1 hour. Once completely dry, the film was sprayed at 30 psi with a CNT solution as the compliant electrode. For single layer films used in the multilayer actuator, CNTs are spray coated onto glass/DE films with paper masks to form patterned electrodes. The conductivity of CNT electrodes is ˜100 kf/square, which is controlled by the amount of solution sprayed per film. After the electrodes are patterned, the paper masks are removed, and the films are sprayed with diluted DE monomer solutions as a binding layer.

The CNT solution is prepared by mixing 5 mg CNT with 2 mL DI water and 20 mL IPA.

### Fabrication of Multilayer PHDE Actuators

DE films are prepared on glass slides and 170 μm thick PET slides via blade coating and in situ UV curing. The films are trimmed to ensure DE film thickness uniformity. The PET/DE film is aligned onto glass/DE film and placed in the chamber of laminator. The laminating machine vacuums the chamber and laminates the sample with a pressure of 2 kg/cm². The stack is placed under UV irradiation in air to cure the binding layer. After UV curing, the stack is heated on a hot plate at 80° C. for 1 min. The PET together with stacked DE films are peeled off from the glass substrate. The process is then repeated for each proceeding layer until the desired number of layers is achieved.

### Fabrication of Spider Actuators

Spider actuators were assembled using Smart Composite Microstructures, a laminate composite fabrication approach previously employed to build insect-inspired robots(59). The mechanisms are comprised of rigid materials (fiber-reinforced plastics, or even paper), cut with a laser, and laminated as a sandwich construction with a polymer flexure (typically polymide). Four-layer DE stacks were fabricated with a 1-inch diameter active area, reinforced around the edge with 3M Fastbond contact adhesive to increase tear resistance and trimmed with a laser cut. The laminate flexures were cut separately and attached to the film using an alignment jig.

### Fabrication of Multifunctional Roll Actuators

The fabrication of the rolled actuators begin with the assembly of a two layer actuator. First, ˜2 g PHDE was deposited onto a 4″ by 5″ glass slide. It was then blade coated at a speed of 1 inch per second to yield a 40 μm film. The PHDE film was cured in a nitrogen environment under UV light. Next, 0.5 mL of a 5 wt % PAA/IPA solution was deposited, and blade coated onto a 4″ by 5″ Kapton substrate. The blade coater had a 0.0005″ gap. The PAA sacrificial layer was allowed to dry for 20 minutes at room temperature. The PHDE casting and curing process was then repeated over the sacrificial layer.

To pattern the electrodes, 8 mL CNT solutions were deposited via spray deposition onto the Glass/PHDE substrate through a contact mask. Each roll was comprised of a 10 cm by 1 cm film with an active length of 9 cm and an active width of 1 cm. For the pump demonstration, rolls with 9 cm by 2 cm active areas were fabricated. 10 mL of diluted DE monomer solutions, which acted as a binding layer, was deposited via spray deposition. The Glass/PHDE substrate was aligned and cured to the PHDE/PAA/Kapton substrate. The bonded structure was then soaked in DI water for 30 minutes to dissolve the sacrificial PAA layer. The Kapton film was then gently peeled away, and the resulting multilayer actuator on glass was allowed to dry at room temperature overnight. The outer CNT electrode was deposited in the same manner as the inner electrode. An outer binding layer was also deposited.

In order to roll the 2-layer actuators, ⅛ inch diameter steel dowels were first wrapped with parchment paper to provide a nonstick surface. Then at 60° C., the 2-layer actuators were slowly rolled onto the parchment-lined dowel ensuring no wrinkles or bubbles formed during the rolling process. After the rolling process was completed, the PHDE roll with ˜20 layers was slipped off the parchment-lined steel dowel and cured under UV light. The ends of the roll were cut to expose the inner electrodes. Carbon grease was smeared on the ends to make electrical contact to the inner electrodes.

The rolled actuators were then incorporated into the pump demonstration using custom 3D-printed luer-lock barb adapters with integrated electrical contacts. The luer-locks allow for a water and air-tight connection to the rest of the fluidic system. Single check valves were placed upstream and downstream from the roll to control flow of the pump. After the fluidic system was primed with a syringe via a three-way stopcock, it could be operated at a variety of frequencies, voltages, and operating angles.

### Energy and Power Density Measurements of PHDE Films in Pure-Shear Mode

PHDE single layer films or 10-layer stacks with 6 cm by 1 cm active area were fabricated and 170 μm thick PET strips with 0.5 cm width were adhered on top and bottom edges of PHDE films with 3M Fastbond to constrain the active films. The samples were tested under isotonic conditions by hanging specific masses at the bottom. Voltages were applied across the film and the actuation strain during contraction of PHDE films were recorded by a digital camera. As the maximum linear strain in these measurements was less than 80% and the stress-strain relationship of PHDE within this strain range was close to linear, the energy and power output of PHDE were calculated based on the potential energy increase of the hanging mass during contraction of the PHDE films, which is half of one actuation cycle.

Permittivity measurement Elastomer materials of known thickness were coated in carbon grease to form circular electrodes with diameter 0.3 inches. Capacitance was measured using GwInstek LCR-819 LCR meter at 1 V excitation and 12 to 1,000 Hz frequency. Relative permittivity e was calculated by:

$$ε = Cz / {ε}_{0} A \qquad Eq . 4$$

Where C is the measured capacitance, z is the thickness of the elastomer film, co is the vacuum permittivity, and A is the effective area.

### Diaphragm Actuation Tests

The electrode coated elastomer films were attached to a diaphragm chamber made of aluminum with a 0.84 cm (0.33 inch) circular opening onto with the DE films were attached. A positive air pressure (˜0.33 kPa) was applied in the chamber such that when the films were actuated, they would deform out of plane to form a raised dome. The active area of the DE films was flat and circular with a diameter of 0.76 cm (0.3 inch), before actuation. A high voltage supply was used to drive the actuation.

A digital camera was used to record the actuation of the DE films. The actuation strain was measured from the video frame-by-frame through MATLAB image processing tools and calculated using an equation for the surface area of a dome.

$${s}_{A} = \frac{( {h}^{2} + {R}^{2} ) - ( {h}_{o}^{2} + {R}_{o}^{2} )}{( {h}_{o}^{2} + {R}_{o}^{2} )} \qquad Eq . 5$$

Where h is the height of the dome and R is the radius. The strain values at each voltage were calculated after a constant driving voltage at 0.1 Hz. The frequency of the voltage was then increased to 0.5 Hz up to 10 Hz. The nominal electric field was calculated by dividing the applied voltage by the initial thickness of the elastomer film at maximum strain. At least three samples were tested for each formulation.

### Dynamic Mechanical Analysis

Mechanical properties were measured on a TA Instruments RSAIII dynamic mechanical analyzer (DMA). Dynamic temperature sweep tests were conducted at a temperature ramping rate of 2° C./min and a frequency of 1 Hz from −50 to 100° C. with samples of 8 mm wide and 50 μm thick loaded onto the DMA with a 10 mm gap between the thin film grips. The maximum elongation strain of the samples were obtained at room temperature with a stretching rate of 0.5 mm/s. The tested samples used were 8 mm wide and 50 μm thick with a 6 mm gap between the thin film grips of the DMA. Samples were measured in triplicate at least.

### Device and Method Embodiments

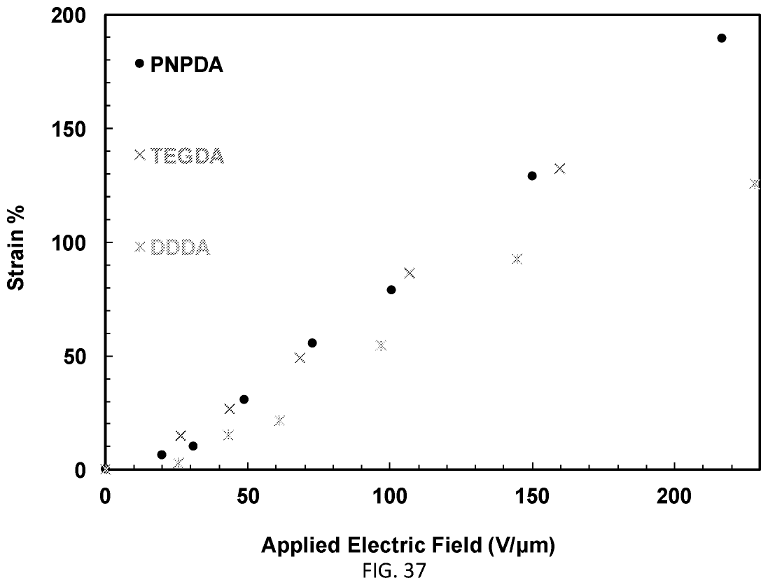

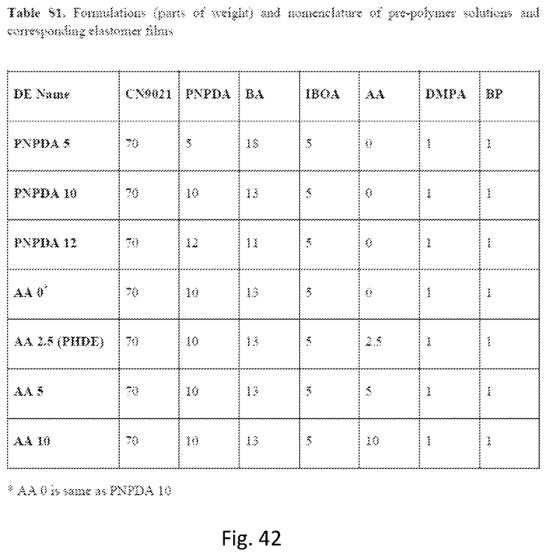

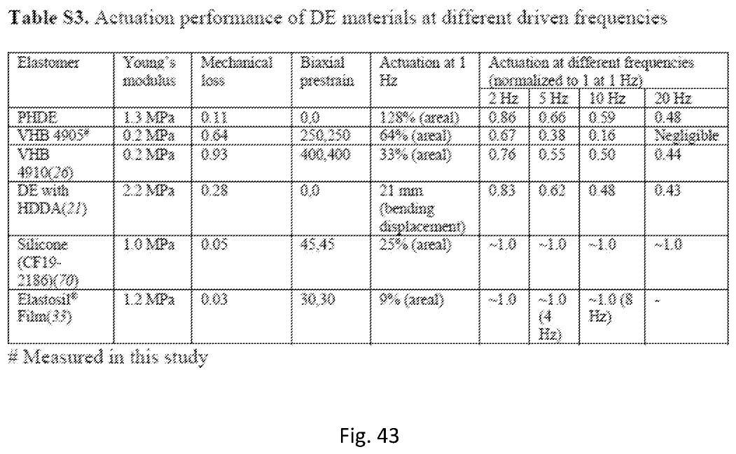

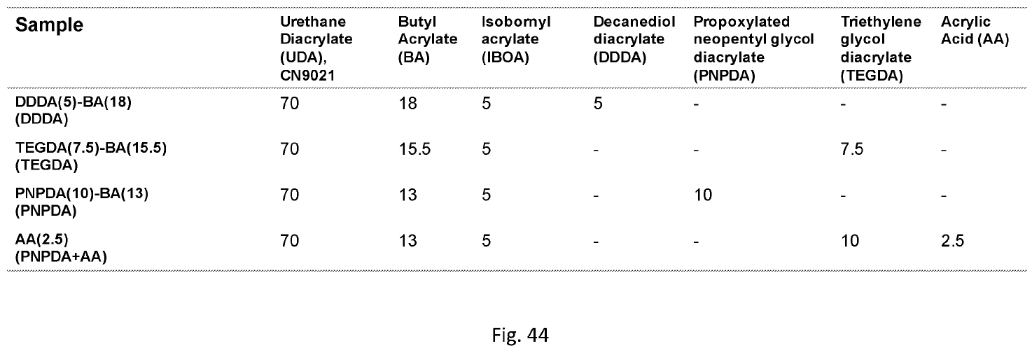

Illustrative, non-exclusive examples of inventive subject matter according to the present disclosure are described in the following enumerated paragraphs (referring also to FIGS. 1-44).

1. FIG. 1F illustrates an example dielectric elastomer 100, comprising or consisting essentially of a crosslinked network 102 (e.g., a polymer) comprising a poly(propylene oxide) unit or moiety 104 on a network chain 106 or a pendant group, wherein the pol(propylene oxide) unit comprises the structure —O—(C₃H₆O)ₙ— and n is and integer greater than or equal to 1. In one or more examples, n is a plurality (e.g., 2≤n≤10) or the unit comprises a plurality of —O—(C₃H₆O— units).

2. The dielectric elastomer of example 1, wherein the crosslinked network 102 is formed by polymerization of a formulation comprising a difunctional monomer comprising a propylene oxide unit or a monofunctional monomer comprising a propylene oxide unit.

2A. The dielectric elastomer of example 1, wherein the crosslinked network 102 is formed by polymerization of a formulation comprising a difunctional monomer comprising a poly(propylene oxide) unit or a monofunctional monomer comprising a poly(propylene oxide) unit, wherein the poly(propylene oxide) unit constitutes 50 wt % or more in the formulation (e.g., in a range of 50 wt-100 wt %, 50 wt %-60 wt %, 50 wt %-70 wt %, 50 wt %-80 wt %, or 50 wt %-90 wt %).

3. The dielectric elastomer of example 1 wherein the crosslinked network 102 is formed by polymerization of a formulation comprising a difunctional monomer comprising a poly(propylene oxide) unit (e.g., to form the long chain crosslinker 104 or first crosslinker 104) having a molecular weight at least 2000 g/mol (e.g., in a range 2000-10000 grams per mole (g/mol)) and a difunctional monomer (e.g., to form the short chain crosslinker 108 or second crosslinker 108) having a molecular weight less than 2000 g/mol (e.g., 200 g/mol≤molecular weight≤1000 g/mol).

4. The dielectric elastomer of example 2, 2A, or 3 wherein the formulation comprises at least one photoinitiator.

5. The dielectric elastomer of example 1, wherein the crosslinked network 102 is formed by polymerization of a formulation comprising an oligomer comprising a urethane unit, a difunctional monomer comprising a propylene oxide unit, a monofunctional reactive diluent, and a photoinitiator.

6. The dielectric elastomer of example 5, wherein the monofunctional reactive diluent is selected from monomers comprising a propylene oxide unit, a butyl group, an isobornyl group, a carboxylic acid group, a 2-ethylhexyl group, or mixtures thereof.

7. The dielectric elastomer of example 4, wherein the oligomer comprising the urethane unit is a difunctional monomer (e.g., to form the short chain crosslinker 108 or second crosslinker 108) having a molecular weight greater than 350 g/mol (e.g., 350≤molecular weight≤2000) or greater than 2000 g/mol (e.g., in a range 2000 g/mol≤molecular weight≤100000 g/mol, e.g., to form the long chain crosslinker 104 or first crosslinker 104).

8. The dielectric elastomer of any of the examples 2 through 7, wherein the formulation comprises at least one polymerizable functional group selected from an acrylate, a methacrylate, or a mixture thereof or the formulation comprises at least one polymerizable functional group comprising at least one of an acrylate, a methacrylate, or a mixture thereof.

9. The dielectric elastomer of the examples 2 through 8, wherein the difunctional monomer comprising the propylene oxide unit has a molecular weight less than 500 g/mol or less than 2000 g/mol (e.g., molecular weight in a range 200 g/mol-2000 g/mol, 200≤molecular weight<2000 g/mol).

10. The dielectric elastomer of example 8, wherein the difunctional monomer comprising the propylene oxide unit comprises an oligo(propylene oxide) and two terminal polymerizable groups.

11. The dielectric elastomer of any of the examples 2-10, wherein the monofunctional monomer comprising the propylene oxide unit comprises an oligo(propylene oxide) with a molecular weight less than 500 g/mol (e.g., in a range 100 g/mol-500 g/mol, or 100 g/mol≤molecular weight<500 g/mol).

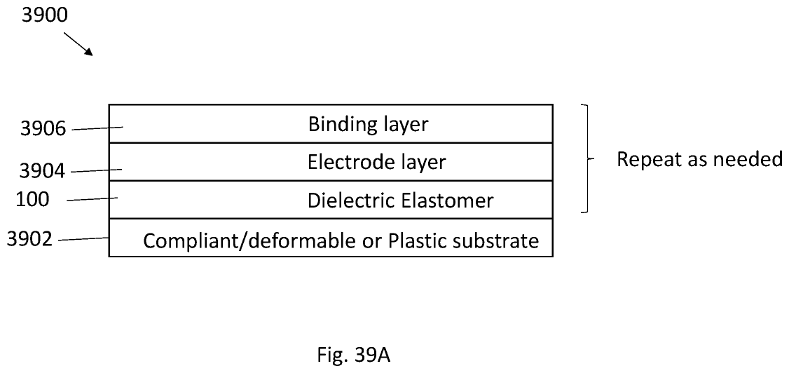

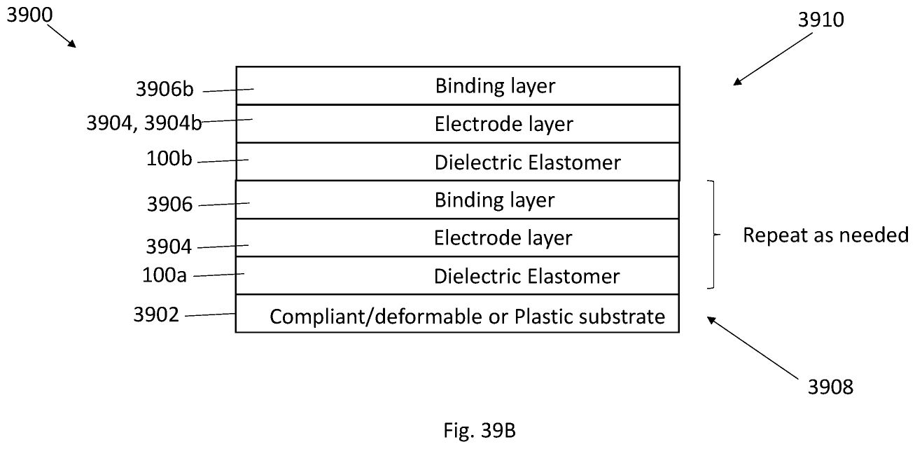

12. FIG. 3 and FIG. 39 illustrate an example actuator 200, 300, 3900 comprising the dielectric elastomer 100 of any of the examples 1-11, further comprising electrodes 302, 3904 on the dielectric elastomer, wherein an electric field applied between two positions on the dielectric elastomer or across a thickness of the dielectric elastomer, in response to a voltage applied to the electrodes, actuates a deformation of stretching the dielectric elastomer that outputs mechanical work.

13. The actuator of example 12, wherein the dielectric elastomer has a strain, including an area strain, greater than at least 20% in response to the electric field less than 150 Volts per micron.

14. The actuator of example 13, wherein the dielectric elastomer maintains the strain after 50 cycles at an actuation frequency of at least 2 Hz.

15. The actuator of example 14, wherein the dielectric elastomer deforms into a dome shape upon application of the electric field using electrodes distributed across the dielectric elastomer.

16. The actuator of example of any of the examples 12-15, comprising a stack 304 of a plurality of the dielectric elastomers.

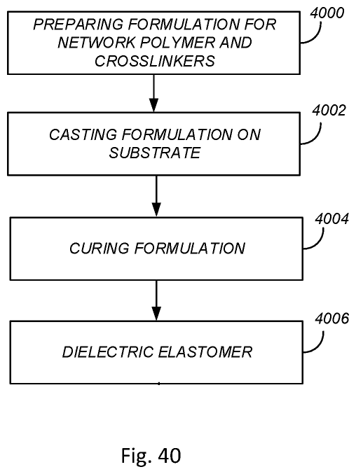

17. FIG. 40 illustrates a process for forming a dielectric elastomer film 100, comprising:
(1) preparation of a liquid formulation (Block 4000) comprising a network 106 forming oligomer and at least a difunctional monomer comprising a propylene oxide unit or a monofunctional monomer comprising a propylene oxide unit (e.g., combining an oligomer and at least one of the difunctional monomer or the monofunctional monomer); and
(2) casting the liquid formulation into a thin (e.g., between 10 microns and 75 microns thick) layer on a substrate (Block 4002), and
(3) curing (Block 4004) the liquid formulation by exposure to at least one of ultraviolet light, visible light, or heat, so that the film (Block 4006) is made.

Example casting includes solution processing such as, but not limited to, spin coating, blade coating, bar coating, spray coating, etc.

18. The process of forming the dielectric elastomer 100 film as in example 17, wherein the substrate is pre-coated with a release agent.

19. The process of forming the dielectric elastomer film as in example 18, wherein the release agent comprises polyacrylic acid, polystyrene sulfonic acid, polystyrene sulfonate, or mixtures thereof.

20. FIG. 3 and FIG. 39A-39B illustrate a multi-layer dielectric elastomer structure 306 comprising two adjacent dielectric elastomer layers 100, 308a, 308b, a layer 3904 of a conductive network 310 sandwiched between the two adjacent dielectric elastomer layers 308a, 308b, and a polymer layer 312, 3906 binding the conductive network 310 and the two adjacent dielectric elastomer layers 308a, 308b.

21. The multi-layer dielectric elastomer structure of example 20, wherein the conductive network is formed by or comprises at least one conductive material selected from the group consisting of single walled carbon nanotubes, multi walled carbon nanotubes, carbon nanopowder, metal nanowires, metal nanoparticles, conductive polymer, and mixtures thereof, or the conductive network is formed by or comprises at least one conductive material selected from or comprising one or more single walled carbon nanotube, one or more multi walled carbon nanotubes, carbon nanopowder, one or more metal nanowires, one or more metal nanoparticles, one or more conductive polymers, or mixtures thereof.

22. The multi-layer dielectric elastomer structure of example 20 or 21, wherein the two adjacent dielectric elastomer layers have the same thickness.

23. The multi-layer dielectric elastomer structure of any of the examples 20-22, wherein the two adjacent dielectric elastomer layers have a thickness in the range between 5 and 100 micrometers.

24. The multi-layer dielectric elastomer structure of any of the examples 20-23, wherein the polymer binding layer is a dielectric elastomer with a thickness less than one tenth of the thickness of the adjacent dielectric elastomer layers.

25. The multi-layer dielectric elastomer structure of example 20, comprising n layers of dielectric elastomer layers, (n−1) layers of the conductive network sandwiched between adjacent dielectric elastomer layers, and (n−1) polymer layers each binding the conductive network and the adjacent ones of the dielectric elastomer layers, where n is 2 or larger.

26. FIG. 3A illustrates a method of preparation of the multi-layer dielectric elastomer structure of example 20, comprising at least:
(1) preparing multiple dielectric elastomer films;
(2) forming the layer of the conducting network on at least one of the multiple dielectric elastomer films;
(3) depositing a layer of a liquid polymerizable formulation onto the layer of the conductive network;
(4) laminating the at least one of the dielectric elastomer films having the conductive network and layer of a liquid polymerizable formulation with another one of the multiple dielectric elastomer films;
(5) curing the layer of liquid polymerizable formulation under ultraviolet (UV) irradiation and/or heating to form the polymer layer binding the conductive network and the two adjacent (laminated) dielectric elastomer layers.

27. The method of preparation of the multi-layer dielectric elastomer structure of example 26, wherein the multiple dielectric elastomer films are formed on a release substrate, and the substrate was removed after the curing step to form the polymer layer binding the conductive network and the two adjacent (laminated) dielectric elastomer layers.

28. FIG. 39 illustrates an actuator comprising the multi-layer dielectric elastomer structure of example 25, further comprising electrodes connected to the layers of the conductive network sandwiched between the two adjacent dielectric elastomer layers, wherein an electric field applied between two positions on the layers of the conductive network, in response to a voltage applied to the electrodes, actuates a deformation of stretching the multi-layer dielectric elastomer that outputs mechanical work.

29. An artificial muscle comprising the dielectric elastomer of any of the examples 1-28.

30. A robot comprising the artificial muscle of example 29, wherein the artificial muscle is used to move or propel the robot or move the robot's limbs.

31. The robot of example 30, wherein the robot uses the artificial muscle to push or jump the robot off the ground.

32. A wearable device, article of clothing, or haptic device, comprising the dielectric elastomer or actuator of any of the examples 1-32.

33. The actuator of any of the examples 12-16 or 28 wherein the dielectric elastomer converts at least 10% of electrical energy inputted through the electrodes into the mechanical work (e.g., converts at 10%-100%, 10%-20%, 10%-30%, 10%-40%, 10%-50%, 10%-60%, 10%-70%, 10%-80%, or 10%-90% of the electrical energy into mechanical work).

34. The actuator of any of the examples 12-16, 28, or 33, wherein the actuator is compliant.

35. The actuator of any of the examples 12-16, 28, or 33, wherein the actuator comprises a deformable capacitor and the electric field generates an electrostatic interaction between the electrodes, known as a Maxwell stress (p), which compresses the dielectric elastomer in the thickness direction and expands it in area.

36. FIG. 1F illustrates an example dielectric elastomer 100, comprising or consisting essentially of a polymer 102 comprising or consisting essentially of a polyacrylate or polymethacrylate 106 crosslinked with crosslinkers 104 comprising at least a poly(propylene oxide) unit or one or more poly(propylene) units.

37. The elastomer of example 36, wherein the polyacrylate 106 comprises a copolymer comprising butyl acrylate (BA) and isobornyl acrylate (IBOA) and the crosslinkers comprise urethane diacrylate (UDA) and propoxylated neopentyl glycol diacrylate (PNPDA).

38. The dielectric elastomer of any of the examples 36-37, wherein the polyacrylate or polymethacryrlate, or a wt % of the components of a copolymer comprising the polyacyrlate or polymethacrylate are selected to achieve a desired Young's modulus, and a wt % of the propylene oxide in the elastomer is selected to tune the cross-linking density so as to tailor a stress-strain relationship and stretch ratio of the dielectric elastomer for use as an actuator outputting mechanical work in response to application of an electric field across the dielectric elastomer.

39. The dielectric elastomer of example 38, wherein the wt % are tailored so that the dielectric elastomer has an area strain, greater than at least 20% in response to an electric field less than 150 Volts per micron applied across the elastomer.

40. The dielectric elastomer of any of the examples 36-39 wherein the crosslinkers include short chains and long chains that are longer and have a larger molecular weight than the short chains and wherein the long chains comprise the poly(propylene oxide) unit or moiety.

41. The dielectric elastomer of any of the examples having the structure illustrated in FIG. 1F or FIG. 1G.

42. FIG. 39 illustrates an actuator comprising the elastomer of any of the examples 36-41.

43. The device of any of the examples 28-35 comprising the dielectric elastomer of any of the examples 36-41.

44. The dielectric elastomer of any of the examples wherein the polypropylene oxide chain is flexible (having a low glass transition temperature), like poly(ethylene oxide) (CH₂CH₂O), but is not hygroscopic and thus has low leakage current at high voltage.

45. The dielectric elastomer of any of the examples having the structure illustrated in FIG. 1f or FIG. 1g. illustrating the polymer comprises both long chains and short chain crosslinkers formulated respectively from a difunctional monomer having a long polypropylene oxide chain and a second difunctional monomer with a short chain. The short chain may or may not comprise polypropylene oxide unit. A monofunctional reactive diluent may also be added.

46. The dielectric elastomer of any of the examples wherein the photoinitiator enables complete curing of the cast films under irradiation with electromagnetic radiation.

47. A dielectric elastomer comprising a crosslinked network comprising —O—(C₃H₆O)ₙ— moiety on a network chain or a pendant group.

48. The dielectric elastomer of any of the examples, wherein the —O—(C₃H₆O)ₙ— moiety comprises at least 50 wt % of the dielectric elastomer.

49. The dielectric elastomer of any of the examples, wherein the poly(propylene oxide) unit —O—(C₃H₆O)ₙ— has two forms, —O—(CH₂CH₂CH₂O)ₙ— and —O—(CH₂CH(CH₃)O)ₙ—.

50. In one or more examples, an oligomer is defined as a monomer containing 2 or more polymerizable functional groups.

52 The dielectric elastomer of any of the examples, wherein the crosslinkers further comprise a first cross-linker 104 comprising at least the poly(propylene oxide) unit and a second cross-linker 108 shorter than the first cross-linker.

53. FIGS. 1A-1G illustrate the dielectric elastomer of any of the examples 1-52, wherein the second cross-linker 108 comprises at least one of PNPDA, TEGDA, DDDA, diacrylates with the linkage being oligo(propylene oxide), oligo(ethylene oxide), or hydrocarbon chains —(CₙH₂ₙ)— where n is between 4 and 24 (or 4≤n≤24). 54. The dielectric elastomer of any of the examples, wherein the network chain (e.g., polyacrylate or polymethacrylate 106) or pendant group comprises side chains forming two-point hydrogen bonded dimers 150 with themselves as well as with the (e.g., —NH— groups) of the network chain and/or crosslinkers (e.g., first cross linker 104, e.g., CN9021, and/or second cross-linker 108, e.g., PNPDA).

55. The Two-point hydrogen bond formation 150 may be formed in the polymer containing acrylic acid.

56. The dielectric elastomer of example 54 or 55, wherein the hydrogen bonded dimers are formed when acrylic acid (AA) (e.g., in a range of 1-10 wt % representing the concentration of the AA in the crosslinked network or polymer 102) is added to the liquid formulation of example 17 and the acrylic acid reacts with the network chain and/or the crosslinkers to form the dimers. (wt % of AA=weight of AA in crosslinked network or polymer/weight of crosslinked network or polymer)×100.

57. The dielectric elastomer of any of the examples, wherein the weight percentage of the crosslinkers (first crosslinkers and second crosslinkers) is in the range of 1-20 wt % (e.g., 1%≤wt %≤20%), and the weight percentage (wt %) represents the concentration of the crosslinkers in the resulting crosslinked network or polymer 102 (wt % of crosslinker=weight of first crosslinker or second crosslinker in the polymer or crosslinked network/weight of polymer or crosslinked network)×100.

58. The dielectric elastomer of any of the examples 1-57, wherein the weight percentage of the first crosslinkers (longer chain cross linkers) is in a range of 3-20 wt. % (e.g., 3%≤wt %≤20%) and the weight percentage of the second crosslinkers (shorter crosslinkers) is in a range of 1-5 wt/o (e.g., 1%≤wt %≤5%).

59. The dielectric elastomer of any of the examples 1-58, wherein a composition, concentration (e.g., wt %) of the network chain and crosslinkers in the dielectric elastomer are selected such that the dielectric elastomer exhibits a rapidly stiffening effect at a strain above a threshold, e.g., an rapidly rising stress when the areal strain is greater than a threshold value, or such that the dielectric elastomer has a relatively low stress at low elongation, but the stress rises rapidly when the elongation reaches a threshold.

$$Linear strain is given by [ [ ( elongated length under deformation ) / ( length without deformation ) ] - 1 ] \times 100.$$

60. The dielectric elastomer of any of the examples 1-59, wherein a composition, concentration (e.g., wt %) of the network chain and crosslinkers in the dielectric elastomer are selected such that the dielectric elastomer exhibits: a stress rising or increasing at a higher rate with strain (e.g., gradient of the stress versus strain curve is higher) at a strain above an areal strain threshold value as compared to the rate (e.g., the gradient) below the areal strain threshold value, and/or a lower stress at lower elongation below a linear strain threshold value as compared to above the linear strain threshold value, and the stress rises or increases at higher rate with strain (e.g., the gradient of the stress versus strain curve is higher) when the elongation is greater than or equal to the threshold linear strain value.

$$\begin{matrix}Areal strain is given by [ [ ( area under deformation ) / ( area without deformation ) ] - 1 ] \times 100 \\ Linear strain is given by [ [ ( linearly elongated length under linear deformation ) / ( length without the linear deformation ) ] - 1 ] \times 100.\end{matrix}$$

61. The dielectric elastomer of examples 59 or 60, wherein the areal strain threshold value is preferably in the range of 100%-300% areal strain (e.g., 100%≤areal strain threshold value≤300%) when the dielectric elastomer is deformed biaxially or the linear strain threshold value is preferably in the range of 50%-150% (e.g., 50%≤linear strain threshold value≤150%) when the dielectric elastomer is deformed linearly.

62. The dielectric elastomer of any of the examples 1-61, wherein a composition, concentration (e.g., wt %) of the network chain and crosslinkers in the dielectric elastomer is selected such that the dielectric elastomer exhibits an areal strain increasing as a function of increasing electrostatically/electric field induced stress (e.g., Maxwell stress) applied to the dielectric elastomer, for areal strains in a range of 0-200% and applied electric fields in a range of 0-150 Volts per micron, and wherein the areal strain is given by:

$$[ [ ( area under deformation ) / ( area without deformation ) ] - 1 ] \times 100.$$

63. The dielectric elastomer of any of the examples, wherein a composition of the dielectric elastomer is selected such that the dielectric elastomer has a permittivity in a range of 4-8 under operation conditions of the dielectric elastomer in an actuator.

64. The dielectric elastomer of any of the examples, wherein a weight percentage/concentration or composition of the second cross linker is selected so that a mechanical loss factor of DE (a measurement of the viscoelasticity), or viscoelasticity, decreases by at least 40% while the stress-strain curve remains unchanged to within 5%, e.g., under operation conditions of an actuator comprising the dielectric elastomer.

65. The dielectric elastomer of any of the examples, wherein a composition and concentration/weight percentage of the second cross linkers is selected to increase stiffness of the dielectric elastomer after a critical stretch ratio wherein the elastomer is driven into its non-Gaussian region and exhibits stress redistribution.

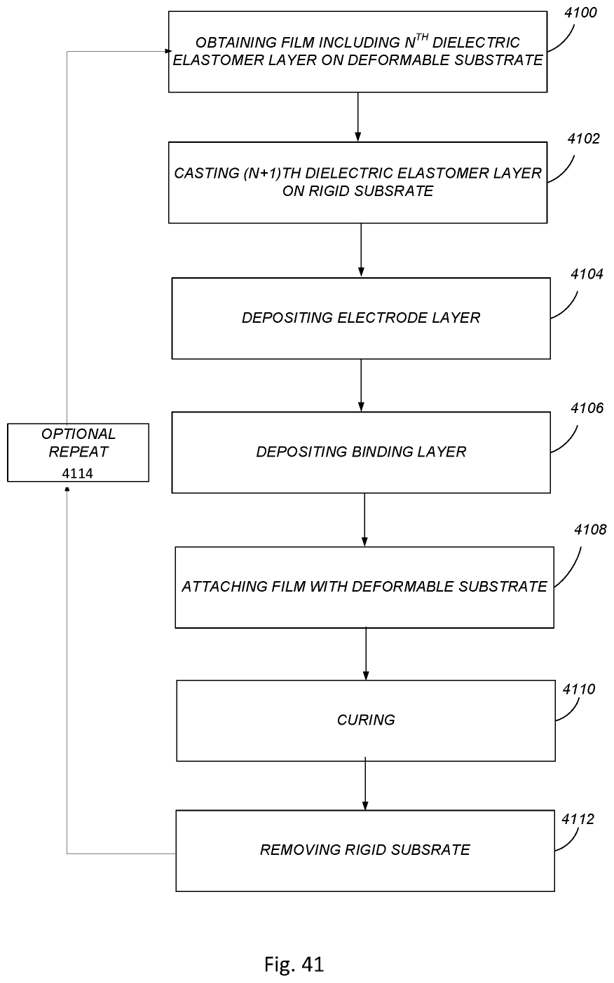

66. FIG. 41 illustrates a method of making a multi-layer actuator comprising n dielectric elastomer layers, m=n−1 electrode layers, and j=n−1 binding layers, comprising, as illustrated in FIG. 39B or FIG. 3A
(a) obtaining a film (Block 4100) comprising an n^{th} dielectric elastomer layer 100, 100a cast on a deformable, compliant, or plastic substrate (e.g., PET) 3902;
(b) casting the (n+1)^{th} dielectric elastomer layer 100b (Block 4102) on a rigid (e.g., glass) substrate 316 having a planar surface;
(c) depositing the m^{th} electrode layer 3904b (Block 4104) on the (n+1)^{th} dielectric elastomer layer;
(d) depositing the j^{th} binding layer 3906b (Block 4106) on the m^{th} electrode layer;
(e) attaching (e.g., laminating and aligning) the film 3908 obtained in step (a) onto the j^{th} binding layer (Block 4108);
(f) curing the j^{th} binding layer 3906b (Block 4110);
(g) removing the rigid substrate (Block 4112) to obtain the film 3910 comprising the j^{th} binding layer binding the m^{th} electrode layer, the n^{th} dielectric elastomer layer, and the (n+1)^{th} dielectric elastomer layer on the deformable substrate;
(h) repeating the sequence of steps (a)-(g) a plurality of times, wherein the film formed in (g) is used as the film in (a) for the next sequence (Block 4114); and so that an actuator comprising n dielectric elastomer layers, n−1 electrode layers, and n−1 binding layers is made on the deformable substrate.

67. The method of claim 66, wherein the laminating comprises vacuum laminating and/or does not use solvents.

68. The multilayer actuator of any of the examples 20-25 manufactured using the method of examples 66 or 67, wherein the electrode layer comprises the conductive network and the binding layer comprises the polymer layer.

### Example Supplementary Characterizations of the Example Dielectric Elastomer

### 1. Structure Characterizations of CN9021 and PNPDA

FIGS. 5A and 5B show the NMR spectra and GPC curve of CN9021, respectively. It has a MW of 40 k Da and a PDI of 1.40. FIG. S1C shows the NMR spectra of PNPDA. It has on average 2 propoxy units (m+n˜2) per molecule.

2. Stress-Strain Relationships and Actuation Performance of DEs with Hexanediol Diacrylate (HDDA) as Short-Chain Crosslinkers

Hexanediol diacrylate (HDDA) was explored as the short-chain crosslinker for DE synthesis(18). Compared to propoxylated neopentyl glycol diacrylate (PNPDA) used in this study, HDDA has a shorter and more rigid alkyl backbone. As a result, when only 5 wt % of HDDA was used as the crosslinker, the DE film exhibited much higher modulus and poorer stretchability than DE with 10 wt % of PNPDA (FIG. 6A). To shape the stress-strain curve, the concentration of HDDA was reduced to 3.5 wt %. The sample showed similar modulus to DE with 10 wt % PNPDA, but lower elongation at break and tensile strength, due to the reduced mesh size of HDDA crosslinked network and increased concentration of butyl acrylate monomer. As a result, DE films with 3.5 wt % of HDDA showed decreased actuation performance in terms of maximum strain and dielectric strength (FIG. 6B).

Compared to short and rigid molecules, short-chain crosslinkers with softer and extended chains can improve the actuation performance of bimodal networked DEs by providing restoring forces at high strains. To demonstrate this synthetic strategy, molecules including propoxylated neopentyl glycol diacrylate (PNPDA), tri(ethylene glycol) diacrylate (TEGDA) and decanediol diacrylate (DDDA) were used as short-chain crosslinkers for syntheses of bimodal networked DE. These molecules have extended backbones when compared to hexanediol diacrylate (HDDA) (FIG. S3A). As shown in FIGS. 7B and 7C, DE systems with these short-chain crosslinkers could be tuned to show similar stress-strain relationship and achieve actuation strains above 130% without EMI. Note that the concentrations of different molecules are varied (5 wt % for DDDA, 7.5 wt % for TEGDA, and 10 wt % for PNPDA). PNPDA crosslinked DE stands out among these materials owing to its higher dielectric constant and strength.

### 4. Swelling Ratio and Gel Fraction of Bimodal Networked DEs

We studied the crosslink densities of our bimodal networked DEs by analyzing their equilibrium swelling ratios (Q) and gel fractions(26). According to Flory-Rehner theory(60), if the degree of swelling is large, the average molecular weight between crosslinks, M_{c}, can be defined as:

$${M}_{c} = 2 ρ {V}_{1} {Q}^{5 / 3} / ( 1 - K )$$

where ρ is the density of the polymer network, V₁ is the molar volume of the solvent, and K is a constant depending on temperature, polymer, solvent, and their interaction. The crosslink density, which is inversely proportional to M_{c}, therefore, has a negative correlation to Q. As shown in FIG. 8, PNPDA 5 has the largest Q of 10.07. Q decreases drastically to 4.08 in PNPDA 10 and then slightly decreases to 3.75 in PNPDA 12. PHDE has a Q of 4.05, which is very close to that of PNPDA 10, indicating that their crosslink densities are similar. With increased concentration of the short-chain crosslinker, the crosslink density in the bimodal networked DE material system is effectively increased. The crosslinkers and monomers have been effectively incorporated into the crosslinked network and thus will contribute to the better rubbery elasticity in such materials. FIG. 8 also shows that PNPDA 5 has the smallest gel fraction of 85.2%. The gel fraction increases to 88.9% and 92.2% in PNPDA 10 and PNPDA 12, respectively. PHDE has an even higher gel fraction of 94.2% due to additional monomers. The high gel fractions indicate that the polymer networks formed are close to ideal(61).

6. FTIR Spectra of Bimodal Networked DEs with Different Concentrations of AA

We measured the FTIR spectra of DE with 0, 2.5, and 10 wt % of acrylic acid (AA), as shown in FIG. 10. Before AA was added, a small amount of hydrogen bonds formed in the bimodal networked DE due to the N—H groups on CN9021 and C═O groups on acrylates. The small peak at 3450 cm⁻¹ was attributed to the stretching of “free” N—H bonds and the peak around 3300 cm⁻¹ was attributed to the stretching of hydrogen-bonded N—H groups(62). After 2.5 wt % of AA was added, the peak at 3450 cm⁻¹ weakened and the peak around 3300 cm⁻¹ became stronger and broader, indicating that more N—H groups on CN9021 were hydrogen-bonded due to the introduction of AA. As the amount of AA was increased to 10 wt %, the peak at 3450 cm⁻¹ almost diminished and a broad band from 3400 to 3200 cm⁻¹ appeared due to the hydrogen bonded O—H groups on AA.

7. Mechanical Properties of Bimodal Networked DEs with Different Concentrations of AA

The mechanical loss factors (tan δ) and stress-strain relationships of DE materials with different amounts of AA added were compared in FIGS. 11A and 11B, respectively. The concentration of PNPDA crosslinker was kept as 10 wt %. After 2.5 parts of AA was added, the mechanical loss factor of DE was decreased from ˜0.22 to ˜0.11 at room temperature and low frequencies while the stress-strain relationship was almost unchanged. The introduced additional hydrogen bonds compensate the decreased covalent crosslinks and help maintain the stress-strain relationship. At the same time, these relatively weak bonds can dynamically dissociate and reassociate, thus “releasing” more free volume for chain movements.

As more AA (5 and 10 parts of weight) was added, hydrogen bonds became highly concentrated in the DE network and the overall covalent crosslinking density (from both long-chain and short-chain crosslinkers) decreases. As a result, the loss factor increased again and the elongation at break of DE decreased significantly. The reason is that, in a polymer network with both covalent and physical crosslinks, intermediate and balanced concentrations of these two crosslinks are essential to obtain good mechanical properties including tensile strength, elongation, and toughness(63, 64). An excess of either crosslink can lead to poor mechanical properties due to highly dense crosslinking or inhomogeneous crosslinking points. In addition, the improved properties of bimodal networks have been ascribed to a synergy between the high modulus of the short chains and the extensibility of the longer ones(65). When the short chains are in excess, the mesh size of a bimodal network is essentially the same as for unimodal networks composed of the same short chains(66). In our system, when large amounts of AA are added, the concentration of CN9021, which serves as the main long segments, decreases a lot and thus leads to poorer extensibility.

Cyclic tensile tests were further conducted on PHDE at different strains (6 cycles for each strain), as shown in FIG. 12. The strain rate is 5% per second. We can see that at 80% and 100% strains, PHDE shows negligible hysteresis, indicating its high elasticity. When the strain is increased to 120%, which is close to the break strain (˜140%), PHDE shows a slightly increased hysteresis. This is due to the increased internal friction after the short chains are stretched. However, the stress of PHDE doesn't decrease and the loading-unloading curves match well during the cyclic tests, indicating that the short chains don't break at this stage.

8. Loss Factor and Storage Modulus of DE with and without AA

FIG. 13A shows the loss factors of DE with and without AA in the temperature range of −50° C. to 100° C. PHDE with 2.5 wt % of AA showed a lower glass transition temperature (T_{g}) when compared to DE without AA, which is indicated by its left shifted loss peak. PHDE also has a lower loss factor at room temperature. These results indicated higher chain mobility of PHDE due to the introduction of weak hydrogen bonds in the network. FIG. 13B shows that the storage modulus of PHDE and DE without AA are comparable at room temperature, indicating that hydrogen bonds act as physical crosslinks and maintain the bimodal network structure of PHDE.

9. Actuation Performance of Bimodal DEs with Different Amounts of AA

When 5 and 10 weight parts of AA are added, the elongation at break of DE decreases significantly and the loss factor increases again due to highly concentrated hydrogen bonds. As a result, the maximum actuation strain of DE decreases (FIG. 14A). The actuation strain of DE at 2 Hz also decreases, indicating lower response speed of DEs with high concentrations of AA (FIG. 14B).

### 10. DMA of PHDE at Different Frequencies

DMA data of PHDE at different frequencies are shown in FIG. 15. The storage modulus and tan δ of PHDE increased rapidly above 20 Hz. This stiffening effect at >20 Hz could be the cause of diminished actuation performance above 20 Hz.

### 11. Modeling Studies on Electromechanical Behaviors of Bimodal Networked DEs

We apply Zhao and Suo's model to explain the electromechanical behaviors of our bimodal networked elastomers(17). According to the model, the electromechanical behavior of DEs is dependent on their voltage-stretch curve Φ(λ), breakdown-stretch curve ω_{b}(λ), and the intersections of these two curves:

$$\begin{matrix}Φ ( λ ) = H {λ}^{- 2} \sqrt{σ ( λ ) / ε} \\ {σ}_{b} ( λ ) = {E}_{B} H {λ}^{- 2}\end{matrix}$$

where λ is the stretch, H the original thickness, σ(λ) the stress-strain relationship, E the dielectric constant, and Ea the electric breakdown strength of the material. We show the curves of our bimodal networked DE materials with 5, 10, and 12 wt % short chain crosslinkers in FIGS. 16A, B, and D, respectively. The curves of PHDE (also with 10 wt % short chain crosslinkers) are shown in FIG. 16C. The voltage-stretch curve of DE with 5 wt % short chain crosslinker reaches a peak and then monotonically decreases, which is similar to non-prestretched VHB and leads to failure due to EMI. When the concentration of short chain crosslinker increases to 10 wt %, the minimum on the voltage-stretch curve is almost eliminated by the steep stiffening of the stress-strain relationship, which indicates the suppression of EMI. The voltage-stretch curve and breakdown-stretch curve of this DE intersects at λ=1.63. PHDE shows very similar behaviors to PNPDA 10 with a plateau on its voltage-stretch curve and the intersection occurs at λ=1.69. The DE with 12 wt % short chain crosslinker has similar behavior while the intersection of two curves is λ=1.58. Based on both experimental and modeling results, we used 10 wt % short chain crosslinker for PHDE synthesis as it suppressed EMI while ensuring high actuation strains. Note that the theoretically predicted values deviate from the experimental strain values, but they follow the same trend. The deviation is probably due to the problematic assumption of estimating biaxial actuation strain with a uniaxial stretch in a much stiffer system.

### 12. Leakage Current Density of PHDE

To measure the leakage current, a circular DE actuator with 0.76 cm diameter was connected to the high voltage supply. A 10 MΩ protection resistor and a ˜6.5 kΩ test resistor were connected in series. A 0.05 Hz square wave signal was applied and the voltage drop across the test resistor as well as the actuation strain were recorded via a multimeter and digital camera, respectively. Strain and leakage current values are recorded after the leakage current reaches a stabilized value. The leakage current densities of the PHDE under different electrical fields are compared to those of VHB 4905, as shown in FIG. 17. Up to 60 V/μm, PHDE has small leakage currents under 0.93 μA/cm². The current rises rapidly above 70 V/μm, similar to the prestretched VHB film.

### 13. Dielectric Constant and Dissipation Factor of PHDE

We measured the dielectric constants and dissipation factors of PHDE in the frequency range of 10 to 1000 Hz and compared them to those of VHB 4905 and bimodal DE without AA. As shown in FIG. 18A, PHDE has a dielectric constant of 5.35 at 1 k Hz, higher than that of VHB 4905 with 250% biaxial prestrain, which is 3.47. The dielectric constant of pre-stretched VHB we measured is close to those from the reference(67). DE without AA has very similar dielectric constants to PHDE and the value at 1 k Hz is 5.59. As shown in FIG. 18B, PHDE also shows a small dielectric dissipation factor of 0.013 at 1 k Hz, which is lower than that of VHB 4905 (0.024 at 1 k Hz).

### 14. Set-Ups for Force Output and Energy Density Measurements of PHDE Films in Pure-Shear Mode

FIGS. 19A and 19B show the set-ups for blocked force and energy density measurements of PHDE films in pure-shear mode. When measuring the blocked force, the samples were clamped on both ends and preloaded under isometric conditions. When measuring the energy density, the samples were under isotonic conditions with different loads.

### 15. Blocked Force of Single Laver PHDE Films in Pure-Shear Mode

The single layer PHDE films were clamped on both ends and preloaded under isometric conditions. The blocked force generated by the film was monitored by measuring the amount of force decrease after the voltages was applied. As shown in FIG. 20A, when 0.6 N pre-load was applied, the blocked force exceeded 0.6 N at 2.5 kV and the film buckled as it entered the compression regime. When 1.2 N pre-load was applied, the PHDE films produced ˜0.95 N force at 2.5 kV and buckled at 3.0 kV, indicative that the blocked force was >1.2 N at 3.0 kV. When 1.4 N pre-load was used, the PHDE films reached a force output of ˜1.2 N at 2.5 kV. However, due to the prestrain induced by the 1.4 N pre-load, the thickness of PHDE films before actuation decreased a lot and these films were susceptible to break down at 3 kV. Thus the single layer PHDE in pure-shear mode was able to output a stable force of ˜0.95 N (˜0.40 MPa stress) at 2.5 kV with a 1.2 N pre-load.

The force output of single layer PHDE films at different frequencies were also measured, as shown in FIG. 20B. With a pre-load of 1.2 N and driving voltage of 2.5 kV, the force decreased to ˜0.67 N (29% reduction) at 2 Hz and ˜0.4 N at 20 Hz.

### 16. Tunable Blocked Force and Energy Density of Bimodal Networked DEs

The force output and energy density of our PHDE can be tuned by adjusting the concentration of the short chain crosslinker. We tested single layer films in the pure-shear mode comprising 5, 10, and 12 wt % PNPDA. 2.5 parts AA were added in all formulations. The modulus of these films increases with higher PNPDA loading. As shown in FIG. 21A, under a pre-load of 1.2 N, the PHDE with 12 wt % PNPDA has the highest blocked force outputs. It reaches ˜1.03 N at 2.5 kV. The DE film with 5 wt % is too soft to withstand the high pre-load and quickly fails at low driving voltages. In a separate experiment, when the pre-load was reduced to 0.6 N, the DE with 5 wt % PNPDA survived at 2.0 kV (FIG. 21B). However, its blocked force is ˜0.1 N lower than that of the PHDE with 10 wt % PNPDA.

The energy density of PHDE films is affected by their forces and strains. We evaluated the performance of bimodal networked DEs with 10 and 12 wt % PNPDA both with 100 g load. From FIG. 22A, we can see that at low driving voltages, these two materials show similar energy density. However, at 2.0 and 2.5 kV, PHDE with 10 wt % PNPDA was able to deliver more work owing to its higher actuation strains. The results are consistent with the actuation strain measurements, as shown in FIG. 22B.

### 17. Life Time Tests of PHDE Films in Pure-Shear Mode

The PHDE exhibited high stability when performing work. FIGS. 23A and 23B show the power outputs and linear displacements of PHDE, respectively, at different testing conditions. At 5 Hz with 100 g load, the PHDE film maintained the power density of ˜660 W/kg after 100,000 cycles. At 10 Hz with 50 g load, the film also maintained a power density of ˜350 W/kg for 100,000 cycles. The films were still functional after these tests. When performing a significant power at resonance (10 Hz and 100 g load), the life time of PHDE decreased to ˜2800 cycles.

### 18. Ball Toss by PHDE Actuators

In order to demonstrate the high energy and power outputs of a single layer PHDE actuator, we configured the DEA to toss a 91 mg ball vertically. The toss was driven by the elastic recovery of the actuator after the applied voltage was removed. The PHDE actuator was actuated at a moderate voltage of 3.4 kV. Note that higher voltages were not used because the ball applied an additional pressure on PHDE thin film, which could easily cause film break at high strains. FIG. 24 shows the photos captured during the ball toss experiment. FIGS. 24A and 24B show the ball on the PHDE actuator at non-actuated and actuated states, respectively. The dome height of actuated PHDE actuator was calculated based on the position change of Aluminum ball and the actuation strain was calculated by Equation 5. The areal actuation strain of PHDE actuator was determined to be 118% (it's higher than that in static actuation test due to the weight of ball) and the energy density of the actuator was calculated to be 0.5 MJ m⁻³. The actuator, which had a diameter of 8.0 mm and a thickness of 0.04 mm, was calculated to have a potential energy of 0.001 J. During the ball toss experiment, the ball reached a maximum height of 0.121 meters. This equates to a potential energy of 0.108 mJ according to Equation S1 where U is the potential energy, m is the mass of the ball, g is acceleration due to gravity, and h is the height of the ball. Therefore, the energy conversion efficiency was about 10%.

$$U = mgh \qquad Eq . S 1$$

### 19. The Jumping Robot Fabricated by PHDE Actuators

A 2 cm diameter single layer actuator was mounted onto a light-weight tripod that acted as a structural base as well as a coupling point to the DE. During actuation, the actuator increases in area which allows an ˜145 mg weighted PET frame, adhered along the circumference of the actuator, to lower, thus lowering the overall center of mass. When the actuator is rapidly discharged, the elastomeric material quickly returns to its original area and restores the weighted PET rings to its original position. This rapid change in center of mass generates sufficient momentum to jump approximately 1.6 cm with an energy conversion rate of about 66% according to a simplistic mechanical model as shown in FIG. 25A. Using the conservation of energy and momentum (Equation S2 and S3, respectively), we can write the velocity of the robot, V₂, as a function of mass 1 and mass 2 (Equation S4). Mass 1 represents the mass of the DE and PET outer ring while mass 2 represents the mass of the leg structure. During the jumping process, there will be two distinct velocities seen between the two masses. The first, V1, involves the PET ring and DE rebounding to its original unactuated position after the applied voltage is removed. After it moves beyond its original position, it will couple to the second mass thus slowing the overall velocity of the robot to V₂. Using basic kinematics equation (Equation S5), we then write the height as a function of mass and the total energy stored in the DE, E_{PE}, derived from the calculated energy density of PHDE and the volume of the actuator. The robot as shown in the manuscript has mass 2 of 14 mg and mass 1 of ˜145 mg which gives us a theoretical height of about 2.4 cm. The height as a function of mass distribution can be seen visually in FIG. 25B.

$${E}_{PE} = \frac{1}{2} {kx}^{2} = \frac{1}{2} {m}_{1} {v}_{1}^{2} \qquad Eq . S 2$$

$${m}_{1} {v}_{1} = ( {m}_{1} + {m}_{2} ) {v}_{2} \qquad Eq . S 3$$

$${v}_{2} = \frac{{m}_{1} {v}_{1}}{{m}_{1} + {m}_{2}} \qquad Eq . S 4$$

$$h = \frac{{v}_{2}^{2}}{2 g} = \frac{{m}_{1}^{2} {v}_{1}^{2}}{{( 2 g ( {m}_{1} + m 2 ) )}^{2}} = \frac{{E}_{PE} {m}_{1}}{{g ( {m}_{1} + {m}_{2} )}^{2}} \qquad Eq . S 5$$

### 21. Swelling Tests on Dry Stacked PHDE

To demonstrate the strong bonding of our dry stacked films, we designed a swelling test. As shown in FIG. 27, we swelled our dry stacked PHDE (with thin binding layer) in THF. Two control samples including physically stacked non-prestretched VHB and physically stacked PHDE (without binding layer) were also soaked for comparison. Before swelling, all three stacks were well adhered and behaved like single films. However, after they were swollen, the VHB films could be easily peeled apart. The physically adhered PHDE films completely delaminated. Our dry stacked PHDE films were still strongly bonded and could be bent without delamination, even though the surface of the swollen films became weak and it could be scratched by the tweezers.

### 22. Mechanical Properties of 10-Layer PHDE Stack

FIG. 28 shows the stress-strain curve and dynamic moduli of a 10-layer PHDE stack, which are very close to those of a single layer film.

### 23. Tunable Thickness of PHDE Films

The thickness of PHDE films can be adjusted by tuning the coating parameters, e.g. the speed of spin coating and the gap of blade coating. We prepared PHDE films with ˜20 μm thickness by blading coating and tested their actuation performance on a diaphragm. As shown in FIG. 29, these films exhibited an areal strain of ˜160% at 1.75 kV, which is close to that of the 40 μm thick films at 3.5 kV. While it's not easy to further decrease the thickness e.g. <10 μm, techniques to prepare and test ultrathin DE films have been reported in the literatures(68, 69). In our opinion, these techniques could be applied to the PHDE and reduce the driving voltage to well below 1 kV.

24. Yield of Actuators from a 10-Layer PHDE Stack

As shown in FIG. 30A, Each batch of 10-layer PHDE stack produces 20 10-layer PHDE actuators. The test results of the maximum driving voltages of the samples from a typical batch are summarized in FIG. 30B. 7 out of the 20 stacks have an operable maximum voltage of 3.5 kV and reached an average areal strain of ˜140%, corresponding to an operating electric field of ˜210 MV/m in the PHDE films. Another 7 stacks show an operable maximum voltage of 3.0 kV. The remainders have further lower maximum voltages. The failure of the actuators at lower voltages were mainly caused by the foreign particles and dust introduced during processing, especially during spray coating of CNTs and the binding layer. The yield should be improved once the spray coating process is carried out in an enclosed and clean coating chamber.

The improved yield can be attributed to the following reasons: 1. The DE films can be examined individually and those with defects can be excluded prior to stacking. 2. The uncured binding layer acts as lubricant to reduce the adhesion during stacking. As a result, before final UV curing of this binding layer, the applied new DE layer can be easily peeled off and laminated again if misalignment or air bubble occurs.

### 25. Dry Stacking of PHDE Stacks

The novel “dry stacking” method can be applied to PHDE stacks. As shown in FIG. 31A, a 10-layer PHDE stack shows high mechanical robustness like thick stiff rubber sheets and can be stacked together by “dry stacking” to form tens of layers of stacks. To do so, one 10-layer PHDE stack is kept on PET substrate and other PHDE stacks are peeled off from substrates and used as freestanding films. CNT electrodes and a thin layer of uncured acrylic polymer precursor acting as a binding layer are sprayed on the freestanding PHDE stacks. To start the stacking, one freestanding PHDE stack is aligned onto the PET/PHDE stack and laminated in a vacuum laminator. After UV curing the precursor layer, another PHDE stack is aligned onto the stack. These processes are repeated until to obtain the desired thickness. FIG. 31B shows the photos of a 30-layer PHDE stack with five actuators.

### 26. Blocked Force, Energy Density and Power Density of 10-Layer PHDE Stacks

FIG. 32A shows blocked force and energy density of 10-layer PHDE stacks tested in pure-shear mode with the same planar dimension as single layer ones. At 2.5 kV, 10-layer PHDE stacks perform ˜8.2 N force under a 12 N pre-load and ˜77 J/kg work density with a 1000 g load. The force output and energy density of 10-layer PHDE stacks were also measured at different frequencies. FIG. 32B shows the force output of 10-layer PHDE stacks tested in pure-shear mode at different frequencies with a driving voltage of 2.5 kV and a pre-load of 12 N. The force decreased to ˜6.7 N at 2 Hz and ˜5.3 N at 20 Hz. FIG. 32C shows that 10-layer PHDE stacks maintained energy densities of ˜48 J/kg and ˜13 J/kg at 2 Hz and 20 Hz, respectively. The driving voltage is 2.5 kV and the load is 1000 g. Based on the energy density measurements, the 10-layer PHDE stacks have an average power density of ˜670 W/kg at 10 Hz and maintain ˜420 W/kg at 5 Hz and ˜510 W/kg at 20 Hz (FIG. 32D).

### 27. Actuation Performance of PHDE Roll Actuators

At 2.5 kV, the PHDE roll actuators generated a linear strain of ˜11.7% with no load and a blocked force of ˜0.70 N (˜0.10 MPa stress) under a 0.5 N compressing pre-load (FIG. 33A). PHDE roll actuators maintain good actuation performance at high frequencies. The linear strain was maintained to ˜8.1% at 2 Hz and ˜4.1% at 20 Hz with 2.5 kV driving voltage (FIG. 33B). The 1 cm active length PHDE roll actuator was able to lift 100 g load with a linear displacement of 1.1 mm at 5 Hz, which demonstrated a 122 W/kg power density of the PHDE roll actuator (FIG. 33C).

### 28. High Robustness of PHDE Rolls

FIG. 34 shows that the PHDE rolls are highly robust and remain functional after they are bent, twisted, and hammered.

### 29. Water Flow Rates of a PHDE Roll Pump

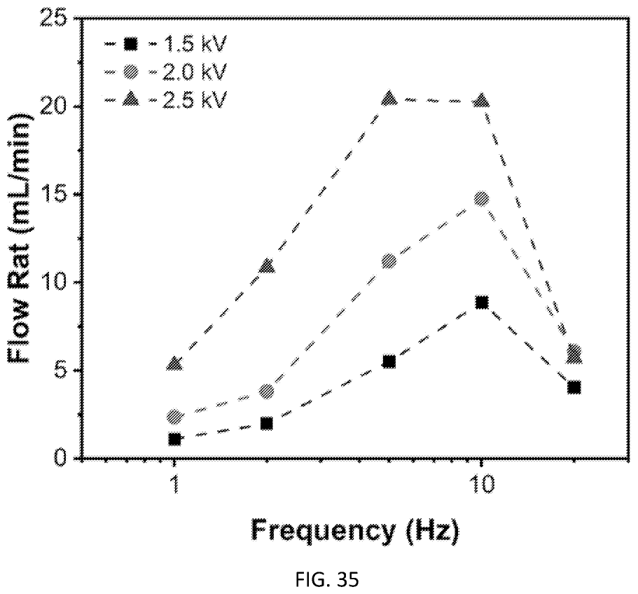

As shown in FIG. 35, the flow rate (L) of PHDE roll pumps could be tuned by controlling the driving voltage and frequency. When used for pumping water, a PHDE roll pump with ˜3 mm inner diameter reached a peak flow rate of ˜20.4 mL/min at 2.5 kV and 10 Hz, which translated to a specific flow rate of ˜100,000 mL/min-kg.

TABLE S2
Elastic modulus of PHDE at different strain levels

| Strain (%) | Modulus (MPa) |
|---|---|
| 5 | 1.34 |
| 30 | 1.33 |
| 50 | 1.34 |
| 70 | 1.50 |
| 90 | 1.93 |
| 110 | 2.87 |
| 130 | 4.86 |

### 30. Further Mechanical Analysis.

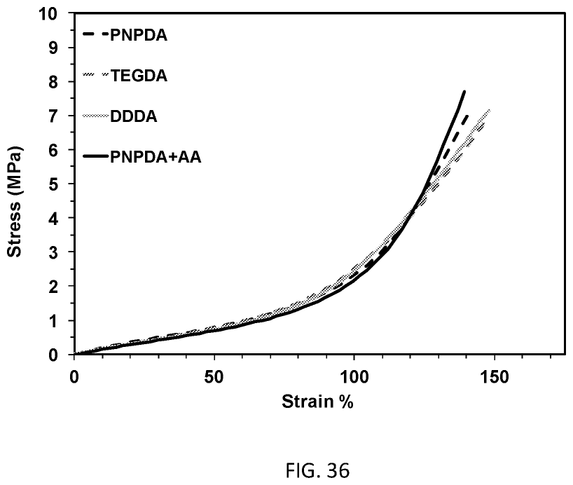

Dynamic mechanical analysis (DMA) was performed to determine the mechanical properties of the three new PHDE systems and ensure the stress-strain curves and moduli were of similar character. FIG. 36A shows the four stress-strain curves of PNPDA-based PHDE, TEGDA-based PHDE, and DDDA-based PHDE. Overall, each formulation exhibited similar mechanical properties. PNPDA had the highest modulus of 2.86 MPa with elongation of 140% and tensile strength of about 7 MPa. TEGDA has a modulus of 2.66 MPa with elongation at break 147% strain and tensile strength of 6.9 MPa. DDDA has a modulus of 1.86 MPa with tensile strength of 7.2 MPa and elongation of 148%. All formulations exhibit a rapid rise in stiffness at high strain with the most pronounced occurring in PNPDA which is indicative of potential for high performance dielectric elastomers as well as EMI suppression.

Actuation tests were performed to determine the performance of the three new PHDE systems (FIG. 36B). PNPDA achieved the highest actuation strain at 186% strain with electric field of 216 V/μm. PNPDA and DDDA have similar electric fields due to the similar chain stiffness. Although, PNPDA contains some carbon-oxygen bonds, it also contains a very stiff tertiary carbon with two methyl groups that will contribute to the chain stiffness. TEGDA and DDDA showed actuation strains at 132% and 125% strain, respectively, but showed distinct differences in applied electric fields. TEGDA exhibited an electric field of 159 V/μm and DDDA achieved an electric field of 228 V/μm. The discrepancy between these two materials likely arises due to the slight difference in chain mobility and stiffness. Although the overall materials exhibit similar mechanical properties, the short chain of DDDA is made up of only carbon-carbon bonds whereas TEGDA is consists of carbon-carbon and carbon-oxygen bonds, which are much more flexible. The stiffer DDDA chain overcomes the higher electric fields. Overall, however, PNPDA achieved the highest actuation performance of the three systems with a high dielectric breakdown field and actuation strain far above the other materials.

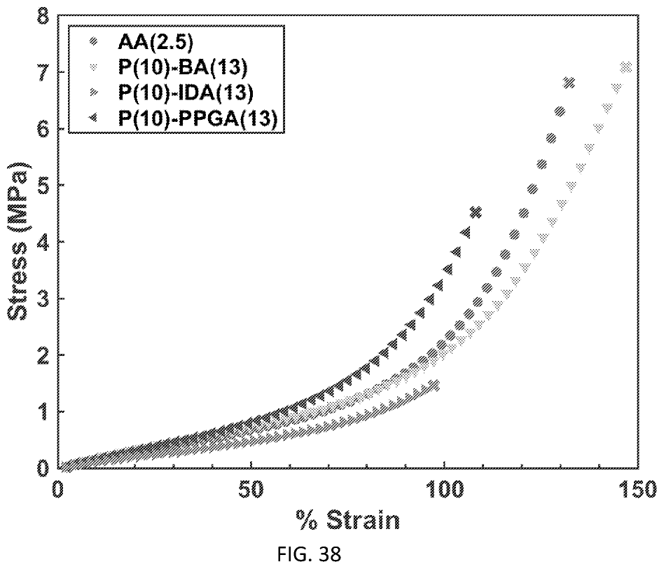

Four DEs were tested using three different monofunctional diluents materials to show the superior performance of AA(2.5) and P(10)-BA(13) compared to other materials. Using carbon grease electrodes, P(10)-BA(13), AA(2.5), P(10)-IDA(13), and P(10)-PPGA(13) single layer actuators were tested. Actuation performance was measured in static actuation tests (FIG. 38A), where the material had a constant voltage applied for 5 seconds, to test the actuation stability, and characterized by Equation S4. Actuation performance for P(10)-IDA(13) was lowest compared with the other spacer materials, with an actuation strain of 125±4.5% and nominal dielectric breakdown field of 109±4.9 V/μm. P(10)-PPGA(13) had high actuation over 150±18.9% strain, however the breakdown field was 108 V/μm, lower than P(10)-IDA(13). The materials with the highest performance were P(10)-BA(13) and P(10)-BA(13)-AA(2.5). P(10)-BA(13) had highest actuation of each formulation with strain of 189% and nominal breakdown field of 135 V/μm. BA proved to be the best spacer material by far, likely due to the short, flexible side chain compared to the longer side chains of the other two spacer materials. The formulation with the highest nominal field was AA(2.5) at 151±4.9 V/μm, and it had a maximum strain of 188±4.5%. P(10)-BA(13). AA(2.5) had very similar actuation performance.

### Advantages and Improvements

Natural muscle is a unique material system that is characterized by its high energy density and ability to cyclically operate at various frequencies and strains. Dielectric elastomer (DE) earned their “artificial muscle” moniker due to their large electrically induced actuation strain, high energy density, fast response speed, and mechanical compliancy, which reproduce or in some aspects exceed the multifunctional performance of natural muscles(1-9). When a DE film is sandwiched between compliant electrodes, it acts as a deformable capacitor and is known as a dielectric elastomer actuator (DEAX(10). When a voltage is applied, the electric field across the DE generates a strong electrostatic interaction between the electrodes, known as a Maxwell stress, which compresses the film in the thickness direction and expands it in area. Based on the working mechanisms, a high-performance DE should have sufficiently high elastic strains, a large dielectric constant, high dielectric strength, and a stress-strain behavior that enables actuation stability at high strains without premature failure.

Unfortunately, it has been challenging to tailor the mechanical and dielectric properties of an elastomer to meet all these requirements, and the selection of DE materials is therefore very limited(11, 12). Commercial 3M VHB™ crylate adhesive tapes and silicone elastomer resins are the most widely used DE materials. VHB films, however, suffer from high viscoelastic losses while silicone elastomers tend to exhibit low maximum strains of 15-20% and low dielectric strength(4, 13-15). In addition, many soft conventional elastomers exhibit a long stress-strain plateau(4, 16) and their performance is limited by electromechanical instability (EMI)(10, 17). Under constant voltage, the electric field increases as the DE film thickness decreases, resulting in progressively greater strain that proceeds until failure or induces unstable snap-through. EMI on some DEs can be suppressed by applying a constant strain onto the DE film prior to actuation, known as prestretching(18-20). This, however, requires a rigid frame to maintain the applied strain, thus diminishing actuators overall flexibility.

Besides material selection, the contradiction between low driving voltages and high energy output limits DEA applications. Multilayer DEAs are able to scale up force and energy outputs at low voltages (6, 21, 22), but processing soft thin films remains very challenging. Currently used “wet stacking” methods, where an uncured DE film is deposited directly on a cured DE, are mostly based on spin or spray coating techniques. This leads to low efficiency, poor scalability, low yield, and suboptimal actuation performance due to non-uniformity of individual DE layers. In addition, “wet” techniques are not applicable for VHBs as they are supplied as cured films and require a large degree of prestretching(23, 24). A commercially available stacked DEA based on silicone elastomers, the only one of its kind on the market, is offered by CTsystems, with a longitudinal strain of 3.3% which is well less than that of skeletal muscle (20%)(25). In order to create a DEA that can achieve force and energy outputs that exceed those of natural muscle, novel materials and fabrication processes must both be developed.

There have been important advances in development of DE materials, including polyacrylates with optimized crosslinking network(26), bottle-brush polymers(16, 27), interpenetrating networked elastomers(28-30), and high dielectric constant silicone elastomers(31-35). A bimodal networked DE material was reported to suppress EMI without prestretching(18). However, it suffered from low maximum strains (<90% areal strain) and high viscoelastic loss which limits the energy and power output needed for practical applications. The synthesis of elastomers that combine the processability and fast response of silicones with the high strain and work density of acrylic elastomers remains an important topic in the field. Such materials, along with an efficient multilayering process, would open the door to many applications for the DEAs, such as compliant motors and soft robotic assemblies.

We have developed systematic strategies to build a novel bimodal networked elastomer and tailor its electromechanical properties for high actuation performance. By tuning the molecular structure of short-chain crosslinkers and introducing a small degree of hydrogen bonding, a DE with highly tunable stress-strain responses and low viscoelasticity has been achieved. Its bimodal network enables a rapid increase in modulus at strains higher than 100%, thus suppressing runaway dielectric breakdown and EMI (FIG. 1A). The resulting processable, high-performance dielectric elastomer (PHDE) shows large-strain, high energy output and fast actuation. This is the first DE material that produces comparable or better actuation performance as highly prestretched DEs without prestretching. In addition, we have also developed a new scalable dry stacking technique and fabricated stacked actuators that achieve comparably high performance as single layer films. PHDE was successfully processed to large-area stacks and various structured actuators.

### REFERENCES

The following references are incorporated by reference herein.
1. R. Pelrine, R. Kornbluh, Q. Pei, J. Joseph, Science 287, 836-839 (2000).
2. R. Pelrine, Q. Pei, R. Kornbluh, Dielectric elastomers: past, present, and potential future. (SPIE, 2018), vol. 10594.
3. R. Shankar, T. K. Ghosh, R. J. Spontak, Soft Matter 3, 1116-1129 (2007).
4. Y. Qiu, E. Zhang, R. Plamthottam, Q. Pei, Acc. Chem. Res. 52, 316-325 (2019).
5. A. O'Halloran, F. O'Malley, P. McHugh, J. Appl. Phys. 104, 071101 (2008).
6. M. Duduta, E. Hajiesmaili, H. Zhao, R. J. Wood, D. R. Clarke, Proc. Natl. Acad Sci. USA 116, 2476-2481 (2019).
7. Y. Chen et al., Nature 575, 324-329 (2019).
8. X. Ji et al., Sci. Robot. 4, eaaz6451 (2019).
9. I. A. Anderson, T. A. Gisby, T. G. McKay, B. M. O'Brien, E. P. Calius, J. Appl. Phys. 112, 041101 (2012).
10. Z. Suo, Acta Mech. Solida Sin. 23, 549-578 (2010).
11. L. J. Romasanta, M. A. Lopez-Manchado, R. Verdejo, Prog. Polym. Sci. 51, 188-211 (2015).
12. Y. Bar-Cohen, I. A. Anderson, Mech. Soft Mater. 1, 5 (2019).
13. P. Brochu, Q. Pei, Macromol. Rapid Commun. 31, 10-36 (2010).
14. S. C. Shit, P. Shah, Natl. Acad. Sci. Lett. 36, 355-365 (2013).
15. S. Rosset, A. Poulin, H. Shea, I. Anderson, Taming the viscoelastic creep of dielectric elastomer actuators. (SPIE, 2019), vol. 10966.
16. M. Vatankhah-Varnoosfaderani et al., Adv. Mater. 29, 1604209 (2017).
17. X. Zhao, Z. Suo, Phys. Rev. Lett. 104, 178302 (2010).
18. X. Niu et al., J. Polym. Sci. B Polym. Phys. 51, 197-206 (2013).
19. J. S. Plante, S. Dubowsky, Smart Mater. Struct. 16, S227-S236 (2007).
20. L. Jiang, A. Betts, D. Kennedy, S. Jerrams, J. Phys. D Appl. Phys. 49, 265401 (2016).
21. M. Duduta, R. J. Wood, D. R. Clarke, Adv. Mater. 28, 8058-8063 (2016).
22. S. Rosset, H. R. Shea, Appl. Phys. Rev. 3, 031105 (2016).
23. G. Kovacs, L. Düring, S. Michel, G. Terrasi, Sens. Actuator A Phys. 155, 299-307 (2009).
24. G. Kovacs, L. During, Contractive tension force stack actuator based on soft dielectric EAP. (SPIE, 2009), vol. 7287.
25. A. Behboodi, S. C. K. Lee, in 2019 IEEE 16th International Conference on Rehabilitation Robotics (ICORR). (2019), pp. 499-505.
26. L.-J. Yin et al., Nat. Commun. 12, 4517 (2021).
27. W. F. M. Daniel et al., Nat. Mater. 15, 183-189 (2016).
28. S. M. Ha et al., High electromechanical performance of electroelastomers based on interpenetrating polymer networks. (SPIE, 2008), vol. 6927.
29. S. M. Ha, W. Yuan, Q. Pei, R. Pelrine, S. Stanford, Adv. Mater. 18, 887-891 (2006).
30. P. Brochu, H. Stoyanov, X. Niu, Q. Pei, Smart Mater. Struct. 22, 055022 (2013).
31. C. Ellingford, C. Bowen, T. McNally, C. Wan, Macromol. Rapid Commun. 39, 1800340 (2018).
32. D. M. Opris et al., Adv. Funct. Mater. 21, 3531-3539 (2011).
33. P. Caspari, S. J. Dunki, F. A. Nuesch, D. M. Opris, J. Mater. Chem. C 6, 2043-2053 (2018).
34. Y. Sheima, P. Caspari, D. M. Opris, Macromol. Rapid Commun. 40, 1900205 (2019).
35. D. M. Opris, Adv. Mater. 30, 1703678 (2018).
36. C. Tugui el al., J. Mater. Chem. C3, 8963-8969 (2015).
37. M. Hayashi, S. Matsushima, A. Noro, Y. Matsushita, Macromolecules 48, 421-431 (2015).
38. H. Gong, Y. Gao, S. Jiang, F. Sun, ACS Appl. Mater. Interfaces 10, 26694-26704 (2018).
39. P. K. T. Oldring, in Chemistry & Technology of UV & FB Formulationsfor Coatings, Inks, & Paints. (SITA Technology, 1991), vol. 2.
40. M. Rubinstein, S. Panyukov, Macromolecules 35, 6670-6686 (2002).
41. L. Zhang et al., J. Mater. Chem. C 8, 2043-2053 (2020).
42. L. Mathis, Y. Chen, K. R. Shull, Macromolecules 51, 3975-3982 (2018).
43. H. Guo, Y. Han, W. Zhao, J. Yang, L. Zhang, Nat. Commun. 11, 2037 (2020).
44. C. L. Lewis, K. Stewart, M. Anthamatten, Macromolecules 47, 729-740 (2014).
45. F. Carpi et al., Smart Mater. Struct. 24, 105025 (2015).
46. S. J. A. Koh et al., J. Mech. Phvs. Solids 105, 81-94 (2017).
47. E. Acome et al., Science 359, 61-65 (2018).
48. H. Stoyanov, P. Brochu, X. Niu, E. D. Gaspera, Q. Pei, Appl. Phys. Let. 100, 262902 (2012).
49. S. Hau, G. Rizzello, S. Seelecke, Extreme Mech. Lett. 23, 24-28 (2018).
50. C. Cao et al., Soft Sci. 1, 1 (2021).
51. S. I. Rich, R. J. Wood, C. Majidi, Nat. Electron. 1, 102-112 (2018).
52. H. S. Jung et al., Int. J. Control Autom. Sys. 15, 25-35 (2017).
53. S. Xu, Y. Chen, N.-s. P. Hyun, K. P. Becker, R. J. Wood, Proc. Natl. Acad. Sci. USA 118, e2103198118 (2021).
54. H. Zhao et al., Adv. Funct. Mater. 28, 1804328 (2018).
55. O. A. Araromi et al., Sens. Actuator A Phys. 167, 459-467 (2011).
56. R. Pelrine et al., Applications of dielectric elastomer actuators. (SPIE, 2001), vol. 4329.
57. Q. Pei, M. Rosenthal, R. Pelrine, S. Stanford, R. Kornbluh, Multifunctional electroelastomer roll actuators and their applcation for biomimetic walking robots. (SPIE, 2003), vol. 5051.
58. V. Cacucciolo et al., Nature 572, 516-519 (2019).
59. R. J. Wood, IEEE Trans. Robot. 24, 341-347 (2008).
60. P. J. Flory, J. R. Jr., J. Chem. Phys. 11, 521-526 (1943).
61. P. Martens, K. S. Anseth, Polymer 41, 7715-7722 (2000).
62. L. Wen, J. Zhang, T. Zhou, A. Zhang, Vib. Spectrosc. 86, 160-172 (2016).
63. J.-Y. Sun et al., Nature 489, 133 (2012).
64. M. Zhong et al., Soft Matter 12, 5420-5428 (2016).
65. C. M. Roland, Rubber Chem. Technol. 86, 351-366 (2013).
66. K. Urayama, T. Kawamura, Y. Hirata, S. Kohjiya, Polymer 39, 3827-3833 (1998).
67. A. Trols et al., Smart Mater. Struct. 22, 104012 (2013).
68. X. Ji et al., Adv. Funct. Mater. 31, 2006639 (2021).
69. A. Poulin, S. Rosset, H. Shea, Fully printed 3 microns thick dielectric elastomer actuator. (SPIE, 2016), vol. 9798.
70. R. Kornbluh, R. Pelrine, Q. Pei, S. Oh, J. Joseph, Ultrahigh strain response of field-actuated elastomeric polymers. (SPIE, 2000), vol. 3987.

### CONCLUSION

This concludes the description of the preferred embodiments of the present disclosure. The foregoing description of the preferred embodiment has been presented for the purposes of illustration and description. It is not intended to be exhaustive or to limit the disclosure to the precise form disclosed. Many modifications and variations are possible in light of the above teaching. It is intended that the scope of rights be limited not by this detailed description, but rather by the claims appended hereto.

1. A dielectric elastomer, comprising:
a crosslinked network comprising a poly(propylene oxide) unit on a network chain or a pendant group, wherein the pol(propylene oxide) unit comprises the structure —O—(C₃H₆O)ₙ— and n is and integer greater than or equal to 1.

2. The dielectric elastomer of claim 1, wherein the crosslinked network is formed by polymerization of a formulation comprising a difunctional monomer comprising a poly(propylene oxide) unit or a monofunctional monomer comprising a poly(propylene oxide) unit, wherein the poly(propylene oxide) unit constitutes or comprises 50 wt % or more in the formulation.

3. The dielectric elastomer of claim 1 wherein the crosslinked network is formed by polymerization of a formulation comprising a difunctional monomer comprising a poly(propylene oxide) unit having a molecular weight at least 2000 g/mol and a difunctional monomer having a molecular weight less than 2000 g/mol.

4. The dielectric elastomer of claim 2, wherein the formulation comprises at least one photoinitiator.

5. The dielectric elastomer of claim 1, wherein the crosslinked network is formed by polymerization of a formulation comprising an oligomer comprising a urethane unit, a difunctional monomer comprising a poly(propylene oxide) unit, a monofunctional reactive diluent, and a photoinitiator.

6. The dielectric elastomer of claim 5, wherein the monofunctional reactive diluent comprises a monomer comprising at least one of a poly(propylene oxide) unit, a butyl group, an isobornyl group, a carboxylic acid group, a 2-ethylhexyl group, or a mixture thereof.

7. The dielectric elastomer of claim 5, wherein the oligomer comprising the urethane unit is a difunctional monomer having a molecular weight greater than 2000 g/mol.

8. The dielectric elastomer of claim 2, wherein the formulation comprises a polymerizable functional group comprising at least one of an acrylate, a methacrylate, or a mixture thereof.

9. The dielectric elastomer of claim 2, wherein the difunctional monomer comprising the poly(propylene oxide) unit has a molecular weight less than 2000 g/mol.

10. The dielectric elastomer of claim 9, wherein the difunctional monomer comprising the poly(propylene oxide) unit comprises an oligo(propylene oxide) and two terminal polymerizable groups.

11. The dielectric elastomer of claim 2, wherein the monofunctional monomer comprising the poly(propylene oxide) unit comprises an oligo(propylene oxide) with a molecular weight less than 500 g/mol.

12. An actuator comprising the dielectric elastomer of claim 1, further comprising electrodes on the dielectric elastomer, wherein an electric field applied between two positions on the dielectric elastomer or across a thickness of the dielectric elastomer, in response to a voltage applied to the electrodes, actuates a deformation or stretching of the dielectric elastomer that outputs mechanical work.

13. The actuator of claim 12, wherein:
the dielectric elastomer has a strain, including an area strain, greater than at least 20% in response to the electric field less than 150 Volts per micron, and
the dielectric elastomer converts at least 10% of electrical energy inputted through the electrodes into the mechanical work, and
the actuator comprises a deformable capacitor and the electric field generates an electrostatic interaction between the electrodes, known as a Maxwell stress (p), which compresses the dielectric elastomer in the thickness direction and expands it in area.

14. The actuator of claim 13, wherein the dielectric elastomer maintains the strain after 50 cycles at an actuation frequency of at least 2 Hz.

15. A multi-layer dielectric elastomer structure comprising two adjacent dielectric elastomer layers each comprising the dielectric elastomer of claim 1, a layer of conductive network sandwiched between the two adjacent dielectric elastomer layers, and a polymer layer binding the conductive network and the two adjacent dielectric elastomer layers.

16. The multi-layer dielectric elastomer structure of claim 15, wherein the conductive network is formed by a conductive material comprising single walled carbon nanotubes, multi walled carbon nanotubes, carbon nanopowder, metal nanowires, metal nanoparticles, conductive polymer, or a mixtures thereof.

17. The multi-layer dielectric elastomer structure of claim 15, wherein the two adjacent dielectric elastomer layers have a same thickness.

18. The multi-layer dielectric elastomer structure of claim 15, wherein the two adjacent dielectric elastomer layers have a thickness in the range between 5 and 100 micrometers or 5≤thickness≤100 micrometers.

19. The multi-layer dielectric elastomer structure of claim 18, wherein the polymer binding layer is a dielectric elastomer with a binder layer thickness less than one tenth of the thickness of the adjacent dielectric elastomer layers.

20. An actuator comprising the multi-layer dielectric elastomer structure of claim 15, further comprising electrodes connected to the layer of the conductive network sandwiched between the two adjacent dielectric elastomer layers, wherein an electric field applied between two positions on the layers of the conductive network, in response to a voltage applied to the electrodes, actuates a deformation or stretching the multi-layer dielectric elastomer that outputs mechanical work.

21.-33. (canceled)
